(19) United States
(12) Patent Application Publication
(10) Pub. No.: US 2023/0080548 A1
(43) Pub. Date: Mar. 16, 2023

(54) ELECTRONIC APPARATUS

(71) Applicant: ROHM Co., LTD., Kyoto (JP)

(72) Inventors: Shinya Hikita, Kyoto (JP); Kenji Fujii, Kyoto (JP); Akinori Nii, Kyoto (JP); Bin Zhang, Kyoto (JP); Hiroaki Aoyama, KYOTO (JP)

(21) Appl. No.: 17/931,256

(22) Filed: Sep. 12, 2022

(30) Foreign Application Priority Data
Sep. 15, 2021 (JP) 2021-150326

(51) Int. Cl. H01L 23/498; H01L 23/06

(52) U.S. Cl. CPC H01L 23/49838; H01L 23/49805; H01L 23/06

(57) ABSTRACT

Provided is an electronic apparatus including an electronic part, a resin member that covers the electronic part, and a plurality of leads each electrically connected to the electronic part, the resin member including a first resin side surface facing one side in a first direction orthogonal to a thickness direction of the resin member, the plurality of leads including a plurality of first side exposed portions arranged along the first resin side surface, each of the plurality of first side exposed portions being exposed from the first resin side surface, each of the plurality of first side exposed portions including a first tapered portion becoming narrower toward the first resin side surface as viewed in the thickness direction, the first tapered portion including a first front surface that faces the same direction as the first resin side surface in the first direction and is flush with the first resin side surface.

### CROSS REFERENCE TO RELATED APPLICATIONS

This application claims priority benefit of Japanese Patent Application No. JP 2021-150326 filed in the Japan Patent Office on Sep. 15, 2021. Each of the above-referenced applications is hereby incorporated herein by reference in its entirety.

### BACKGROUND

The present disclosure relates to an electronic apparatus.

In the past, there has been a leadless-package electronic apparatus, such as a small outline non-leaded (SON) package and a quad flat non-leaded (QFN) package. In the leadless-package electronic apparatus, terminals for external connection do not protrude from a sealing resin that seals electronic parts, and the leadless-package electronic apparatus is advantageous for reducing the size and thickness of the electronic apparatus. A leadless-package semiconductor apparatus including a semiconductor chip as an electronic part is disclosed in, for example, Japanese Patent Laid-open No. 2008-112961.

The semiconductor apparatus described in Japanese Patent Laid-open No. 2008-112961 includes a semiconductor chip, a plurality of leads, and a sealing resin. The plurality of leads include, for example, copper. Each of the plurality of leads is a terminal for external connection that is electrically connected to the semiconductor chip through a thin metal wire and that is used to mount the semiconductor apparatus on a circuit board of electronic equipment or other equipment. The sealing resin covers the semiconductor chip. Such a semiconductor apparatus is manufactured by using, for example, a molded array packaging (MAP) system. In the MAP system, the sealing resin is used to seal a plurality of semiconductor chips all together on a lead frame, and then the plurality of semiconductor chips sealed on the lead frame are diced into pieces each including one semiconductor chip.

### SUMMARY

An example of the dicing includes a method of blade dicing, and the lead frame (a plurality of leads) and the sealing resin are cut all together. In the dicing, metal as a material of the lead frame is sometimes extended together as a result of the cut, and a burr (hereinafter, referred to as a “metal burr”) may be generated on the lead frame (lead). Such a metal burr may, for example, short-circuit the leads adjacent to each other, causing a malfunction. Hence, the distance between the leads adjacent to each other needs to be appropriately reserved in the semiconductor apparatus (electronic apparatus) in the related art, in order to suppress the short circuit of the leads caused by the metal burrs. Therefore, a reduction in the distance between the leads adjacent to each other is limited in the semiconductor apparatus (electronic apparatus) in the related art, and downsizing of the apparatus in plan view is not easy.

The present disclosure has been made in view of the circumstances, and it is desirable to provide an electronic apparatus that can be downsized while short circuit of leads adjacent to each other is suppressed.

According to an embodiment of the present disclosure, there is provided an electronic apparatus including an electronic part, a resin member that covers the electronic part, and a plurality of leads each electrically connected to the electronic part, in which the resin member includes a first resin side surface facing one side in a first direction orthogonal to a thickness direction of the resin member, the plurality of leads include a plurality of first side exposed portions arranged along the first resin side surface, each of the plurality of first side exposed portions being exposed from the first resin side surface, each of the plurality of first side exposed portions includes a first tapered portion that becomes narrower toward the first resin side surface as viewed in a thickness direction, and the first tapered portion includes a first front surface that faces the same direction as the first resin side surface in the first direction and that is flush with the first resin side surface.

The electronic apparatus according to an embodiment of the present disclosure is capable of being downsized while short circuit between leads adjacent to each other is suppressed.

### BRIEF DESCRIPTION OF THE DRAWINGS

FIG. 1 is a perspective view illustrating an electronic apparatus according to a first embodiment of the present disclosure, illustrating a state viewed from a bottom surface side;

FIG. 2 is a plan view illustrating the electronic apparatus according to the first embodiment, illustrating a resin member represented by an imaginary line;

FIG. 3 depicts an electronic part represented by an imaginary line in the plan view of FIG. 2;

FIG. 4 is a bottom view illustrating the electronic apparatus according to the first embodiment;

FIG. 5 is a partially enlarged view of part of FIG. 4;

FIG. 6 is a partially enlarged view of part of FIG. 4;

FIG. 7 is a partially enlarged view of part of FIG. 4;

FIG. 8 is a partially enlarged view of part of FIG. 4;

FIG. 9 is a front view illustrating the electronic apparatus according to the first embodiment;

FIG. 10 is a back view illustrating the electronic apparatus according to the first embodiment;

FIG. 11 is a right side view illustrating the electronic apparatus according to the first embodiment;

FIG. 12 is a left side view illustrating the electronic apparatus according to the first embodiment;

FIG. 13 is a cross-sectional view taken along line XIII-XIII of FIG. 3;

FIG. 14 is a cross-sectional view taken along line XIV-XIV of FIG. 3;

FIG. 15 is a cross-sectional view along a line XV-XV of FIG. 3;

FIG. 16 is a cross-sectional view along a line XVI-XVI of FIG. 3;

FIG. 17 is a cross-sectional view along a line XVII-XVII of FIG. 3;

FIG. 18 is a bottom view illustrating one step of a manufacturing method of the electronic apparatus according to the first embodiment;

FIG. 19 is a bottom view illustrating one step of the manufacturing method of the electronic apparatus according to the first embodiment;

FIG. 20 is a cross-sectional view illustrating one step of the manufacturing method of the electronic apparatus according to the first embodiment;

FIG. 21 is a bottom view illustrating one process of the manufacturing method of the electronic apparatus according to the first embodiment;

FIG. 22 is a bottom view illustrating one step of the manufacturing method of the electronic apparatus according to the first embodiment;

FIG. 23 is a cross-sectional view illustrating one step of the manufacturing method of the electronic apparatus according to the first embodiment;

FIG. 24 is a bottom view illustrating one step of the manufacturing method of the electronic apparatus according to the first embodiment;

FIG. 25 is a cross-sectional view illustrating one step of the manufacturing method of the electronic apparatus according to the first embodiment;

FIG. 26 is a bottom view illustrating an electronic apparatus according to a first modification of the first embodiment;

FIG. 27 is a cross-sectional view illustrating the electronic apparatus according to the first modification of the first embodiment, corresponding to the cross section illustrated in FIG. 13;

FIG. 28 is a cross-sectional view illustrating the electronic apparatus according to the first modification of the first embodiment, corresponding to the cross section illustrated in FIG. 14;

FIG. 29 is a cross-sectional view illustrating the electronic apparatus according to the first modification of the first embodiment, corresponding to the cross section illustrated in FIG. 17;

FIG. 30 is a bottom view illustrating an electronic apparatus according to a second modification of the first embodiment;

FIG. 31 is a bottom view of main parts illustrating an electronic apparatus according to a third modification of the first embodiment;

FIG. 32 is a bottom view of main parts illustrating the electronic apparatus according to the third modification of the first embodiment;

FIG. 33 is a bottom view illustrating an electronic apparatus according to a fourth modification of the first embodiment;

FIG. 34 is a bottom view illustrating an electronic apparatus according to another modification of the first embodiment;

FIG. 35 is a bottom view illustrating an electronic apparatus according to another modification of the first embodiment;

FIG. 36 is a bottom view illustrating an electronic apparatus according to another modification of the first embodiment;

FIG. 37 is a bottom view illustrating an electronic apparatus according to another modification of the first embodiment;

FIG. 38 is a bottom view of main parts illustrating a first tapered portion of an electronic apparatus according to another modification of the first embodiment;

FIG. 39 is a bottom view of main parts illustrating a first tapered portion of an electronic apparatus according to another modification of the first embodiment;

FIG. 40 is a bottom view of main parts illustrating a first tapered portion of an electronic apparatus according to another modification of the first embodiment;

FIG. 41 is a bottom view of main parts illustrating a first tapered portion of an electronic apparatus according to another modification of the first embodiment;

FIG. 42 is a plan view illustrating an electronic apparatus according to a second embodiment of the present disclosure, illustrating a resin member represented by an imaginary line;

FIG. 43 is a bottom view illustrating the electronic apparatus according to the second embodiment; and

FIG. 44 is a plan view illustrating an electronic apparatus according to a modification of the second embodiment, illustrating a resin member represented by an imaginary line.

### DETAILED DESCRIPTION OF THE PREFERRED EMBODIMENTS

An electronic apparatus according to preferred embodiments of the present disclosure will now be described with reference to the drawings. The same signs are provided to the same or similar constituent elements, and duplicate description will appropriately be omitted. Such terms as “first,” “second,” and “third” in the present disclosure are simply used as labels, and the terms are not necessarily intended to add a permutation to the objects.

In the present disclosure, “an object A being formed on an object B” and “an object A being formed over an object B” include “an object A being directly formed on an object B” and “an object A being formed on an object B with another object placed between the object A and the object B” unless otherwise stated. Similarly, “an object A being arranged on an object B” and “an object A being arranged over an object B” include “an object A being directly arranged on an object B” and “an object A being arranged on an object B with another object placed between the object A and the object B” unless otherwise stated. Similarly, “an object A being positioned over an object B” includes “an object A being positioned over an object B with the object A in contact with the object B” and “an object A being positioned over an object B with another object placed between the object A and the object B” unless otherwise stated. In addition, “an object A overlapping an object B as viewed in a certain direction” includes “an object A overlapping the entire object B” and “an object A overlapping part of an object B” unless otherwise stated.

### First Embodiment

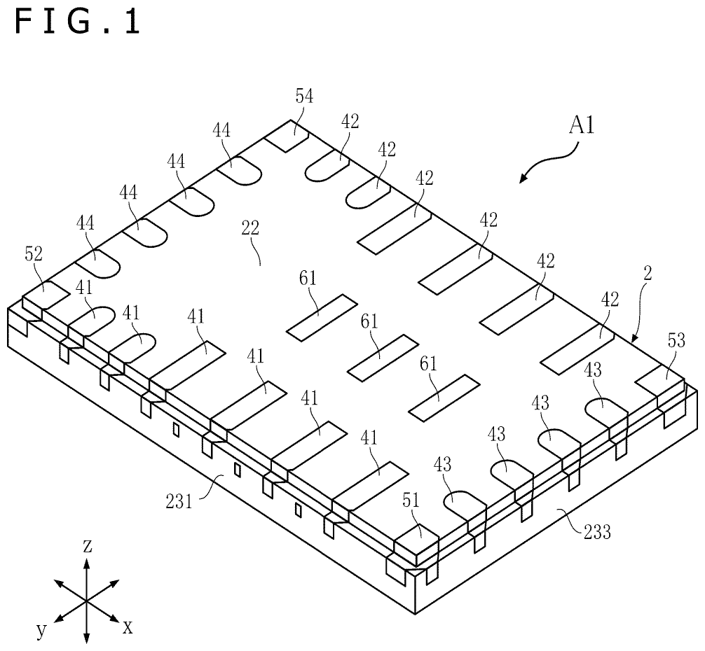

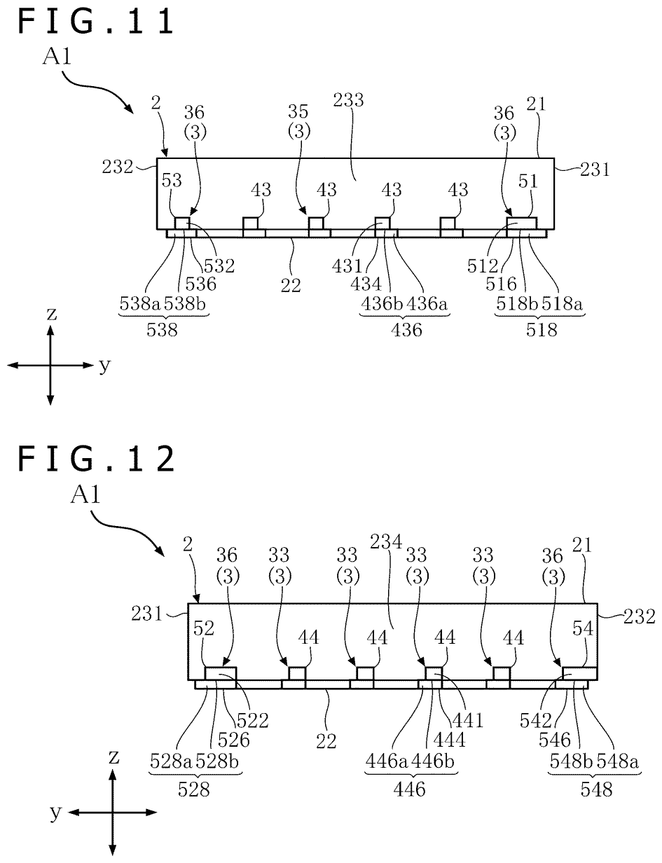

FIGS. 1 to 17 illustrate an electronic apparatus A1 according to a first embodiment of the present disclosure. The electronic apparatus A1 includes an electronic part 1, a resin member 2, and a plurality of leads 3. The plurality of leads 3 include a plurality of first leads 31, a plurality of second leads 32, a plurality of third leads 33, a plurality of fourth leads 34, a fifth lead 35, and a plurality of sixth leads 36.

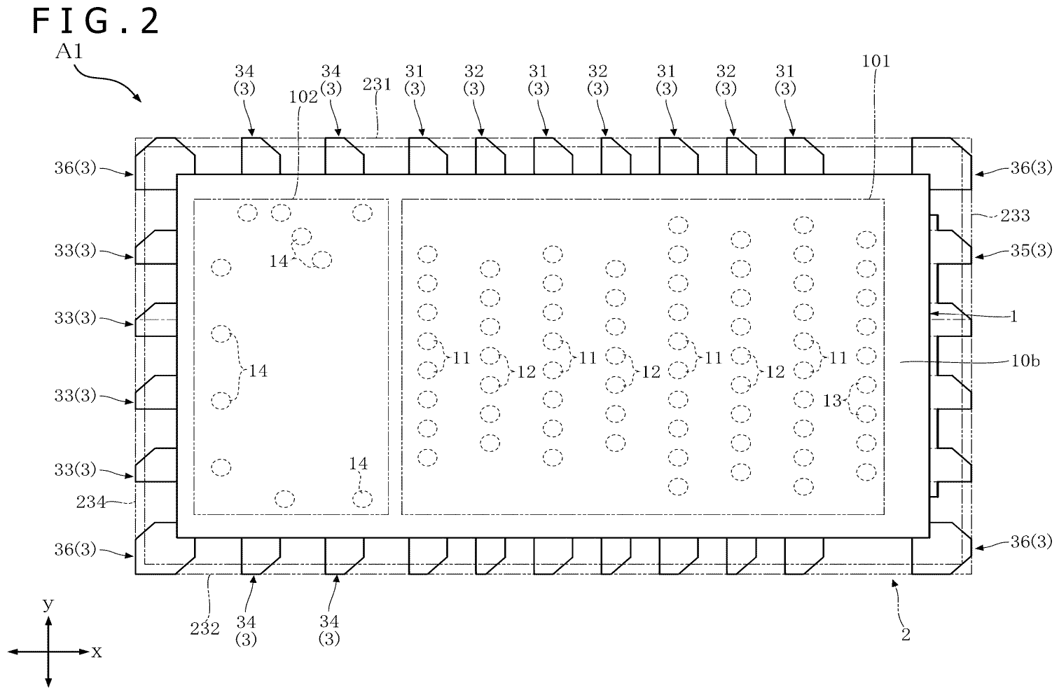

For the convenience of description, a thickness direction of the electronic apparatus A1 (resin member 2) will be referred to as a “thickness direction z.” In the following description, one side in the thickness direction z may be referred to as an upper side, and another side may be referred to as a lower side. Note that such description as “over,” “under,” “upper side,” “lower side,” “upper surface,” and “lower surface” indicate relative positional relations between parts and sections, for example, in the thickness direction z, and the terms may not define relations with the gravity direction. “In plan view” represents a view in the thickness direction z. A direction orthogonal to the thickness direction z will be referred to as a “first direction y,” and a direction orthogonal to the thickness direction z and the first direction y will be referred to as a “second direction x.” The first direction y is a vertical direction in a plan view of the electronic apparatus A1 (see FIG. 2). The second direction x is a horizontal direction in the plan view of the electronic apparatus A1 (see FIG. 2). In the present disclosure, an upper side of FIG. 2 will be referred to as one side in the first direction y, and a lower side of FIG. 2 will be referred to as another side in the first direction y. A right side of FIG. 2 will be referred to as one side in the second direction x, and a left side of FIG. 2 will be referred to as another side in the second direction x.

The electronic apparatus A1 is a surface mount package. As illustrated in FIG. 1, the package structure of the electronic apparatus A1 is, for example, MAP type QFN. The electronic apparatus A1 is, for example, rectangular in plan view as illustrated in FIG. 2.

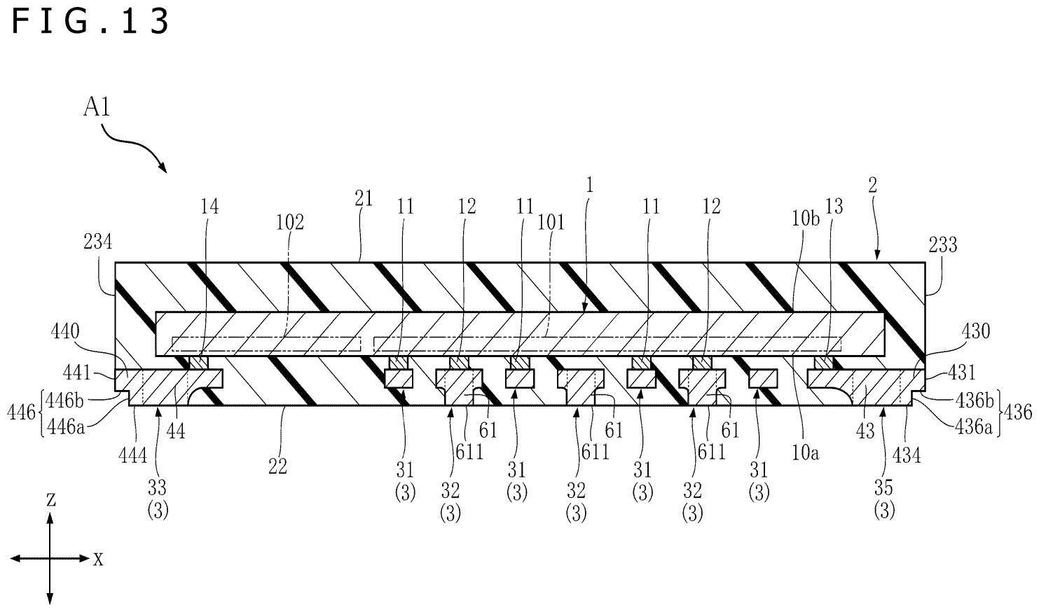

The electronic part 1 is an element that fulfills an electrical function of the electronic apparatus A1. The electronic part 1 is, for example, rectangular in plan view. The electronic part 1 is, for example, an integrated circuit element including a semiconductor. In the present embodiment, the electronic part 1 includes a switching circuit 101 and a control circuit 102 as illustrated in FIGS. 2 and 13. The switching circuit 101 includes a semiconductor switch such as a metal oxide semiconductor field effect transistor (MOSFET) and an insulated gate bipolar transistor (IGBT). The switching circuit 101 is divided into two regions including a high voltage region (upper arm circuit) and a low voltage region (lower arm circuit). The switching circuit 101 converts, for example, input direct current (DC) power (DC voltage) into alternating current (AC) power (AC voltage). The control circuit 102 includes, for example, a gate driver that drives the switching circuit 101. The electronic part 1 may be an active functional element (such as a transistor and a diode) or a passive functional element (such as a resistor, a capacitor, and an inductor) instead of the integrated circuit element.

The electronic part 1 includes an element main surface 10a and an element back surface 10b as illustrated in FIGS. 13 to 17. The element main surface 10a and the element back surface 10b are separated in the thickness direction z and face opposite sides. The element main surface 10a faces the lower side in the thickness direction z, and the element back surface 10b faces the upper side in the thickness direction z. In the present embodiment, flip chip bonding is used to connect the electronic part 1 to the plurality of leads 3, and the element main surface 10a faces the plurality of leads 3 as illustrated in FIGS. 13 to 17.

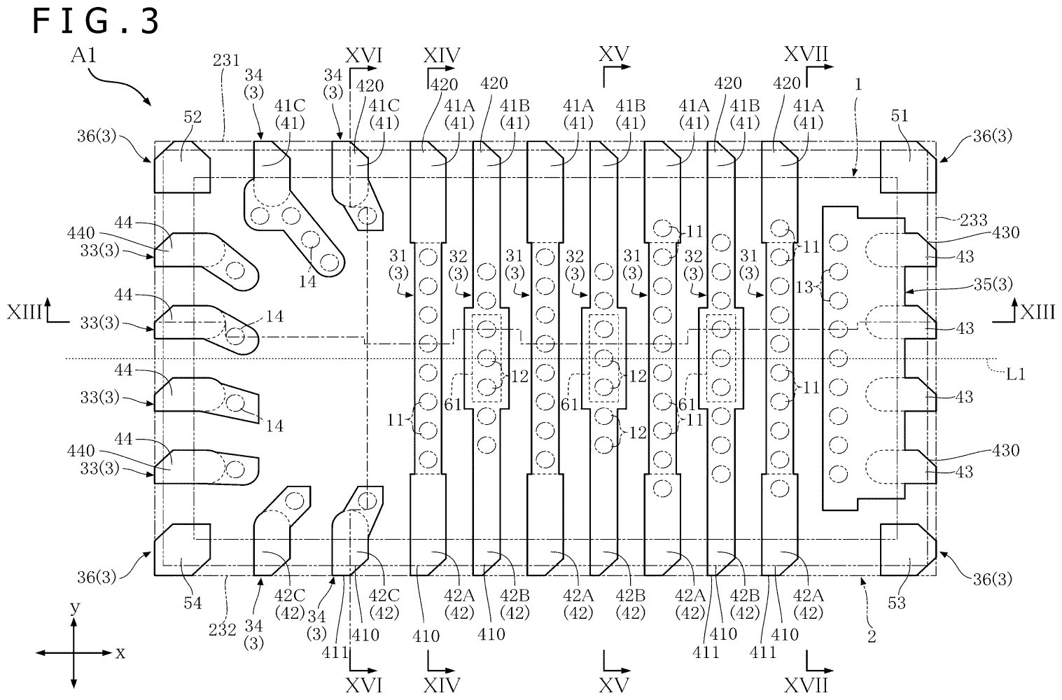

The electronic part 1 is provided with a plurality of electrodes 11 to 14 on the element main surface 10a as illustrated in FIGS. 2, 3, and 13 to 17. The number, the arrangement, the shape, and the dimension in plan view of the plurality of electrodes 11 to 14 are not limited to the illustrated example, and they are appropriately changed according to the electronic part 1 to be used. The plurality of electrodes 11 to 13 are electrically connected to the switching circuit 101. As illustrated in FIG. 3, the plurality of electrodes 11 are connected to the plurality of first leads 31. The plurality of electrodes 12 are connected to the plurality of second leads 32. The plurality of electrodes 13 are connected to the fifth lead 35. The plurality of electrodes 14 are electrically connected to the control circuit 102. As illustrated in FIG. 3, the plurality of electrodes 14 include electrodes 14 each connected to one of the plurality of third leads 33 and include electrodes 14 each connected to one of the plurality of fourth leads 34.

The resin member 2 is a sealing material that protects the electronic part 1. The resin member 2 contains an insulating resin material. The resin material is, for example, a black epoxy resin. As illustrated in FIGS. 1 to 17, the resin member 2 covers part of each of the plurality of leads 3 and covers the electronic part 1. The resin member 2 is rectangular in plan view as illustrated in FIG. 2. The resin member 2 includes a resin main surface 21, a resin back surface 22, a first resin side surface 231, a second resin side surface 232, a third resin side surface 233, a fourth resin side surface 234, a first resin recessed portion 241, a second resin recessed portion 242, a third resin recessed portion 243, and a fourth resin recessed portion 244.

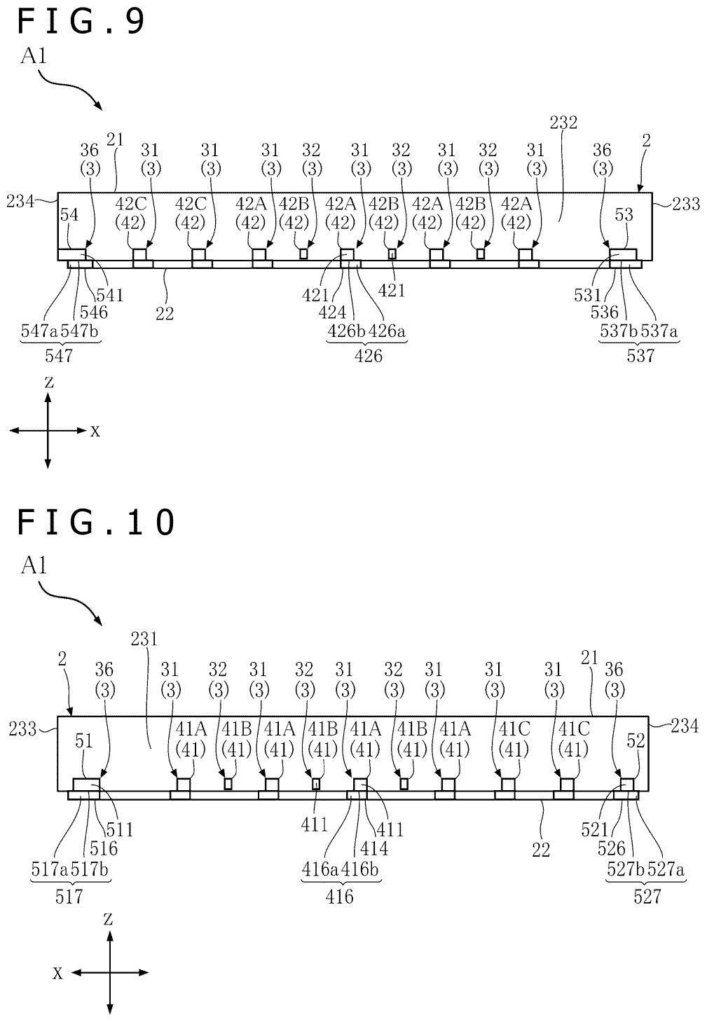

The resin main surface 21 and the resin back surface 22 are separated in the thickness direction z and face opposite sides as illustrated in FIGS. 9 to 17. The resin main surface 21 faces the upper side in the thickness direction z, and the resin back surface 22 faces the lower side in the thickness direction z. The resin main surface 21 is an uppermost surface in the resin member 2, and the resin back surface 22 is a lowermost surface in the resin member 2.

The first resin side surface 231 and the second resin side surface 232 are separated in the first direction y and face opposite sides as illustrated in FIGS. 2 to 4, 11, 12, and 14 to 17. The first resin side surface 231 faces one side in the first direction y, and the second resin side surface 232 faces the other side in the first direction y. Each of the first resin side surface 231 and the second resin side surface 232 is placed between the resin main surface 21 and the resin back surface 22 in the thickness direction z. The first resin side surface 231 is connected to the resin main surface 21 and is connected to the resin back surface 22 through the first resin recessed portion 241. The second resin side surface 232 is connected to the resin main surface 21 and is connected to the resin back surface 22 through the second resin recessed portion 242. The first resin side surface 231 and the second resin side surface 232 are each flat.

The third resin side surface 233 and the fourth resin side surface 234 are separated in the second direction x and face opposite sides as illustrated in FIGS. 2 to 4, 9, 10, and 13. The third resin side surface 233 faces one side in the second direction x, and the fourth resin side surface 234 faces the other side in the second direction x. The third resin side surface 233 and the fourth resin side surface 234 are placed between the resin main surface 21 and the resin back surface 22 in the thickness direction z. The third resin side surface 233 is connected to the resin main surface 21 and is connected to the resin back surface 22 through the third resin recessed portion 243. The fourth resin side surface 234 is connected to the resin main surface 21 and is connected to the resin back surface 22 through the fourth resin recessed portion 244. The third resin side surface 233 and the fourth resin side surface 234 are each flat.

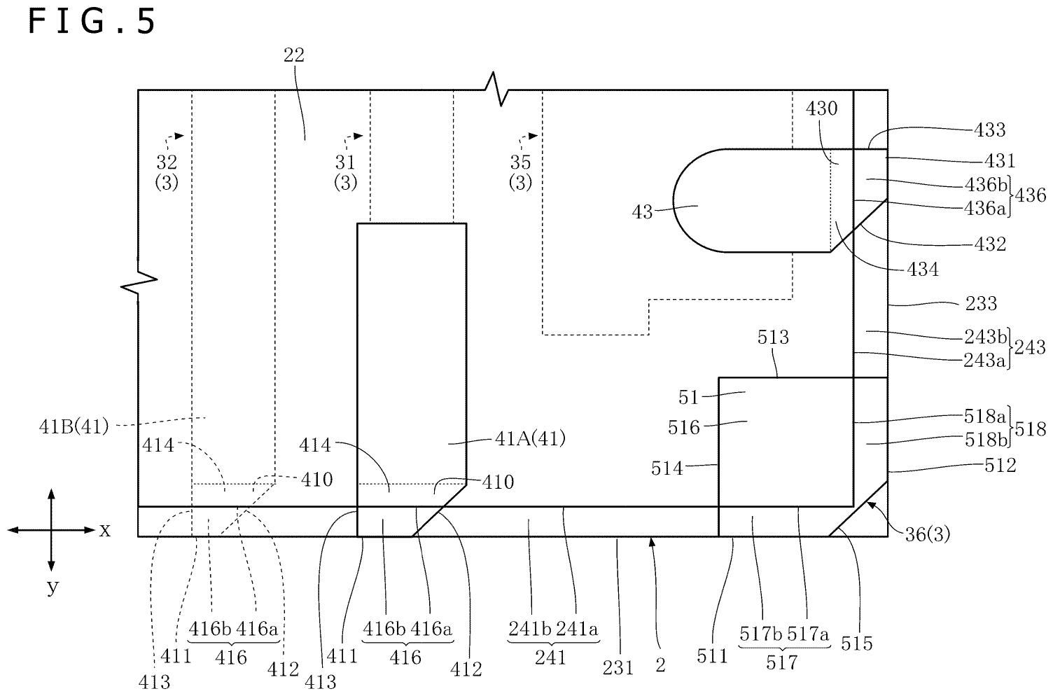

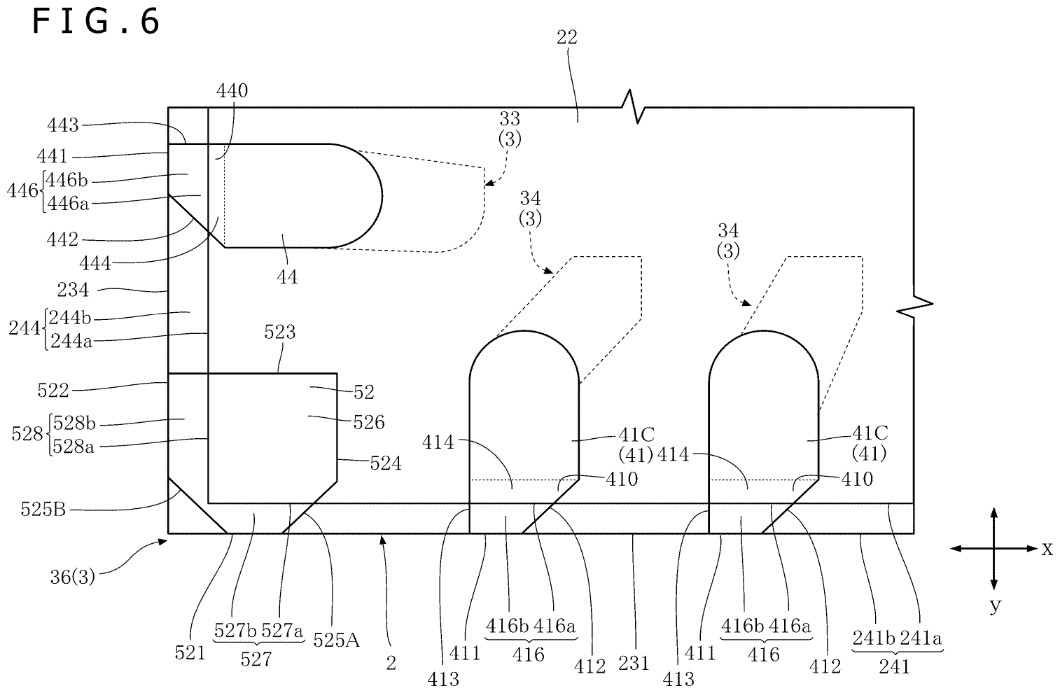

The first resin recessed portion 241 is recessed from the resin back surface 22 and connected to the first resin side surface 231 as illustrated in FIGS. 15 and 17. As illustrated in FIGS. 5, 6, 15, and 17, the first resin recessed portion 241 includes a first wall surface 241a and a first bottom surface 241b. The first wall surface 241a faces the same direction as the first resin side surface 231. As illustrated in FIGS. 5 and 6, the first wall surface 241a is positioned on the other side in the first direction y with respect to the first resin side surface 231, that is, the inner side of the electronic apparatus A1 in plan view with respect to the first resin side surface 231. The first bottom surface 241b is connected to the first resin side surface 231 and the first wall surface 241a. In the example illustrated in FIGS. 15 and 17, the first bottom surface 241b is flat and faces the lower side in the thickness direction z. Unlike the example, the first bottom surface 241b may be curved in a recessed shape.

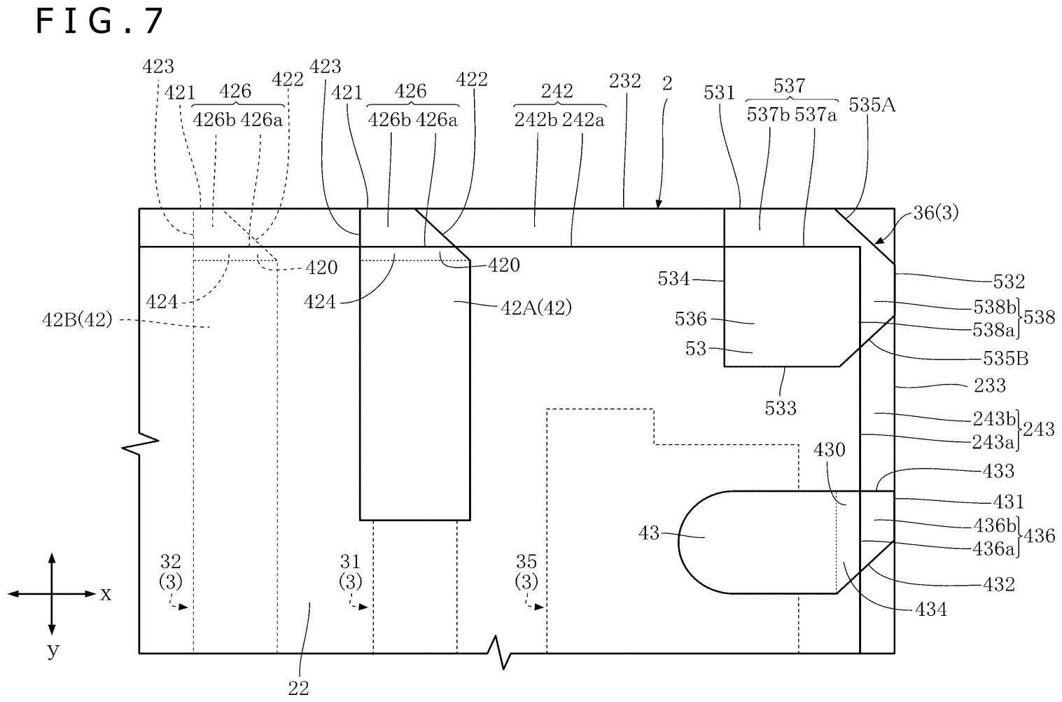

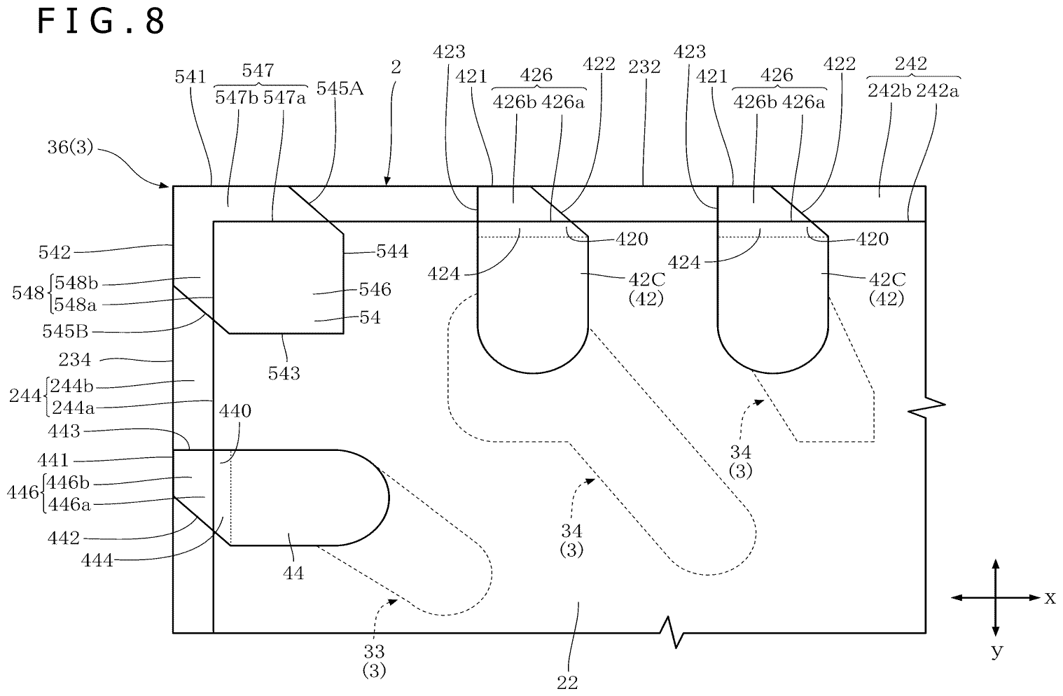

The second resin recessed portion 242 is recessed from the resin back surface 22 and connected to the second resin side surface 232 as illustrated in FIGS. 15 and 17. As illustrated in FIGS. 7, 8, 15, and 17, the second resin recessed portion 242 includes a second wall surface 242a and a second bottom surface 242b. The second wall surface 242a faces the same direction as the second resin side surface 232. As illustrated in FIGS. 7 and 8, the second wall surface 242a is positioned on the one side in the first direction y with respect to the second resin side surface 232, that is, the inner side of the electronic apparatus A1 in plan view with respect to the second resin side surface 232. The second bottom surface 242b is connected to the second resin side surface 232 and the second wall surface 242a. In the example illustrated in FIGS. 15 and 17, the second bottom surface 242b is flat and faces the lower side in the thickness direction z. Unlike the example, the second bottom surface 242b may be curved in a recessed shape.

The third resin recessed portion 243 is recessed from the resin back surface 22 and connected to the third resin side surface 233. As illustrated in FIGS. 5 and 7, the third resin recessed portion 243 includes a third wall surface 243a and a third bottom surface 243b. The third wall surface 243a faces the same direction as the third resin side surface 233. As illustrated in FIGS. 5 and 7, the third wall surface 243a is positioned on the other side in the second direction x with respect to the third resin side surface 233, that is, the inner side of the electronic apparatus A1 in plan view with respect to the third resin side surface 233. The third bottom surface 243b is connected to the third resin side surface 233 and the third wall surface 243a. The third bottom surface 243b is, for example, flat and faces the lower side in the thickness direction z, as with the first bottom surface 241b and the second bottom surface 242b. Unlike the example, the third bottom surface 243b may be curved in a recessed shape.

The fourth resin recessed portion 244 is recessed from the resin back surface 22 and connected to the fourth resin side surface 234. As illustrated in FIGS. 6 and 8, the fourth resin recessed portion 244 includes a fourth wall surface 244a and a fourth bottom surface 244b. The fourth wall surface 244a faces the same direction as the fourth resin side surface 234. As illustrated in FIGS. 6 and 8, the fourth wall surface 244a is positioned on the one side in the second direction x with respect to the fourth resin side surface 234, that is, the inner side of the electronic apparatus A1 in plan view with respect to the fourth resin side surface 234. The fourth bottom surface 244b is connected to the fourth resin side surface 234 and the fourth wall surface 244a. The fourth bottom surface 244b is, for example, flat and faces the lower side in the thickness direction z, as with the first bottom surface 241b and the second bottom surface 242b. Unlike the example, the fourth bottom surface 244b may be curved in a recessed shape.

The dimension of the resin member 2 in the thickness direction z (dimension from the resin back surface 22 to the resin main surface 21 along the thickness direction z) is, for example, equal to or greater than 400 μm but equal to or smaller than 1,000 μm. The dimension of the resin member 2 in the first direction y (dimension from the first resin side surface 231 to the second resin side surface 232 along the first direction y) is, for example, equal to or greater than 1,000 μm but equal to or smaller than 10,000 μm. The dimension of the resin member 2 in the second direction x (dimension from the third resin side surface 233 to the fourth resin side surface 234 along the second direction x) is, for example, equal to or greater than 1,000 μm but equal to or smaller than 10,000 μm. Note that the dimensions are not limited to the illustrated ranges of values.

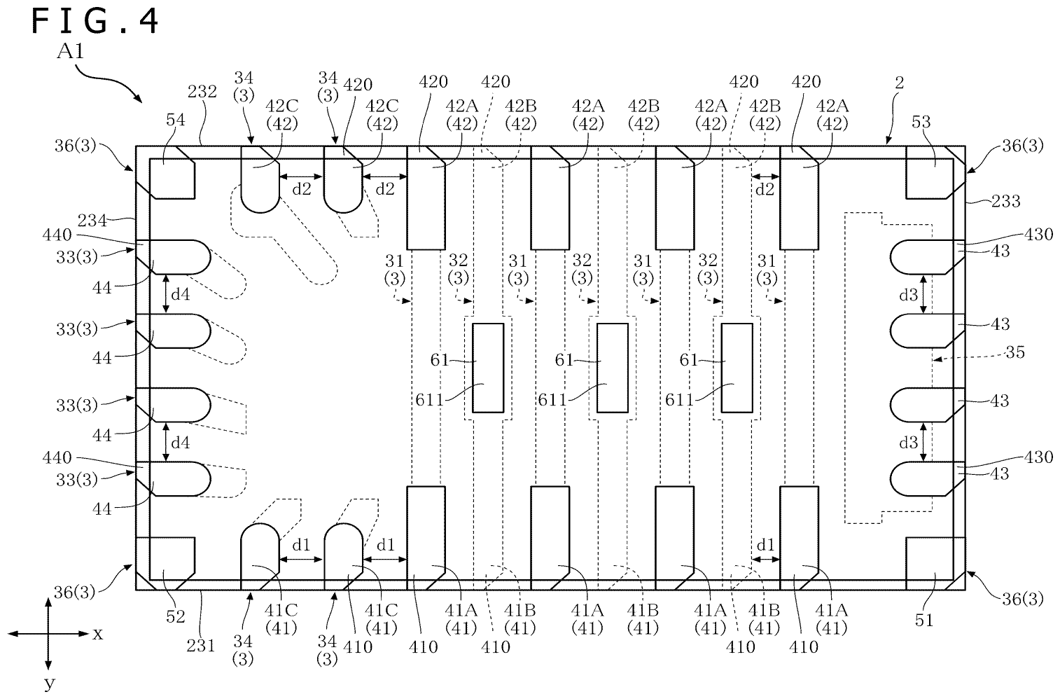

The plurality of leads 3 are appropriately electrically connected to the electronic part 1. The plurality of leads 3 contain copper or a copper alloy. The plurality of leads 3 include the plurality of first leads 31, the plurality of second leads 32, the plurality of third leads 33, the plurality of fourth leads 34, the fifth lead 35, and the plurality of sixth leads 36 as illustrated in FIGS. 3, 4, and other drawings.

Each of the plurality of first leads 31 extends along the first direction y as illustrated in FIGS. 3, 4, and 14. The plurality of first leads 31 are arrayed at predetermined intervals in the second direction x in plan view as illustrated in FIGS. 3 and 4. Each electrode 11 of the electronic part 1 is attached to a different one of the plurality of first leads 31. Each of the plurality of first leads 31 is partially exposed from the resin member 2. In each first lead 31, the part exposed from the resin member 2 (first side exposed portion 41A and second side exposed portion 42B described later) is, for example, an input terminal (P terminal) that receives DC power (voltage) to be converted in the electronic apparatus A1.

Each of the plurality of second leads 32 extends along the first direction y as illustrated in FIGS. 3, 4, and 15. The plurality of second leads 32 are arrayed at predetermined intervals in the second direction x in plan view as illustrated in FIGS. 3 and 4. Each of the plurality of second leads 32 is arranged between a pair of first leads 31 adjacent to each other in the second direction x. The plurality of first leads 31 and the plurality of second leads 32 are alternately arrayed in the second direction x. Each electrode 12 of the electronic part 1 is attached to a different one of the plurality of second leads 32. Each of the plurality of second leads 32 is partially exposed from the resin member 2. In each second lead 32, the part exposed from the resin member 2 (back surface exposed portion 61 described later) is, for example, an output terminal of AC power (voltage) converted by the switching circuit 101 included in the electronic part 1.

Each of the plurality of third leads 33 is positioned on the other side in the second direction x with respect to the plurality of first leads 31 as illustrated in FIGS. 3, 4, and 13. Each electrode 14 of the electronic part 1 is attached to a different one of the plurality of third leads 33. Each of the plurality of third leads 33 is partially exposed from the resin member 2. In each third lead 33, the part exposed from the resin member 2 (fourth side exposed portion 44 described later) is, for example, one of an input terminal of power (voltage) for driving the control circuit 102 of the electronic part 1, an input terminal of an electrical signal to be transmitted to the control circuit 102, and an output terminal of an electrical signal to be transmitted from the control circuit 102.

Each of the plurality of fourth leads 34 is positioned between the plurality of first leads 31 and the plurality of third leads 33 in the second direction x as illustrated in FIGS. 3 and 4. Each electrode 14 of the electronic part 1 is attached to a different one of the plurality of fourth leads 34. Each of the plurality of fourth leads 34 is partially exposed from the resin member 2. In each fourth lead 34, the part exposed from the resin member 2 (first side exposed portion 41C and second side exposed portion 42C described later) is, for example, either an input terminal of an electrical signal to be transmitted to the control circuit 102 of the electronic part 1 or an output terminal of an electrical signal to be transmitted from the control circuit 102.

The fifth lead 35 is positioned on the one side in the second direction x with respect to the plurality of first leads 31 as illustrated in FIGS. 3, 4, and 13. Each electrode 13 of the electronic part 1 is attached to the fifth lead 35. The fifth lead 35 is partially exposed from the resin member 2. In the fifth lead 35, the part exposed from the resin member 2 (third side exposed portion 43 described later) is, for example, an input terminal (N terminal) that receives DC power (voltage) to be converted in the electronic apparatus A1.

The plurality of sixth leads 36 are arranged on four corners of the resin member 2 in plan view as illustrated in FIGS. 3 and 4. The plurality of sixth leads 36 include a lead 36 arranged near the corner of the resin member 2 including the first resin side surface 231 and the third resin side surface 233 as illustrated in FIG. 5, a lead 36 arranged near the corner of the resin member 2 including the first resin side surface 231 and the fourth resin side surface 234 as illustrated in FIG. 6, a lead 36 arranged near the corner of the resin member 2 including the second resin side surface 232 and the third resin side surface 233 as illustrated in FIG. 7, and a lead 36 arranged near the corner of the resin member 2 including the second resin side surface 232 and the fourth resin side surface 234 as illustrated in FIG. 8. In the present embodiment, the plurality of sixth leads 36 are not electrically connected to the electronic part 1.

As illustrated in FIGS. 3 to 16, the plurality of leads 3 include a plurality of first side exposed portions 41, a plurality of second side exposed portions 42, a plurality of third side exposed portions 43, a plurality of fourth side exposed portions 44, a first corner exposed portion 51, a second corner exposed portion 52, a third corner exposed portion 53, a fourth corner exposed portion 54, and a plurality of back surface exposed portions 61.

Each of the plurality of first side exposed portions 41 is exposed from the first resin side surface 231 as illustrated in FIGS. 3, 4, and 10. The plurality of first side exposed portions 41 are arranged along the first resin side surface 231 as illustrated in FIGS. 3 and 4. Accordingly, the plurality of first side exposed portions 41 are arrayed in the second direction x. The plurality of first side exposed portions 41 include a plurality of first side exposed portions 41A, 41B, and 41C as illustrated in FIGS. 3 and 4. The plurality of first side exposed portions 41A are formed on the plurality of first leads 31. The plurality of first side exposed portions 41B are formed on the plurality of second leads 32. The plurality of first side exposed portions 41C are formed on the leads 34 that are arranged along the first resin side surface 231 and that are among the plurality of fourth leads 34. In the present embodiment, each interval d1 (see FIG. 4) between the first side exposed portions 41 adjacent to each other in the second direction x is, for example, equal to or greater than 50 μm but equal to or smaller than 250 μm. Particularly, the interval d1 between the first side exposed portion 41A and the first side exposed portion 41B adjacent to each other in the second direction x is short in the example illustrated in FIGS. 3 and 4, and the interval d1 is, for example, equal to or greater than 50 μm but equal to or smaller than 200 μm.

As illustrated in FIGS. 5 and 6, each of the plurality of first side exposed portions 41 (the plurality of first side exposed portions 41A to 41C) includes a first tapered portion 410. The first tapered portion 410 is a section of each of the first side exposed portions 41A to 41C that becomes narrower toward the first resin side surface 231 in plan view. The first tapered portion 410 is formed on an end portion on the one side in the first direction y in plan view in each of the first side exposed portions 41A and 41C, that is, on an end portion on the outer side of the electronic apparatus A1 in plan view. As illustrated in FIGS. 5 and 6, the first tapered portion 410 includes a first front surface 411, a first chamfered portion 412, a first side surface 413, and a first back surface 414.

The first front surface 411 faces the same direction as the first resin side surface 231 and is flush with the first resin side surface 231 as illustrated in FIGS. 5, 6, and 14 to 16. The first front surface 411 is flat. In the present disclosure, unless otherwise stated, being “flush” includes not only a mode in which two or more surfaces form an ideal smooth surface, but also a case in which there is unavoidable roughness formed during the cut in the manufacturing step of the electronic apparatus A1 as well as a case in which cut marks are formed across the surfaces.

The first chamfered portion 412 is connected to the first front surface 411 as illustrated in FIGS. 5 and 6. The first chamfered portion 412 is formed on the one side in the second direction x in the first tapered portion 410. The first chamfered portion 412 is inclined with respect to the first front surface 411 in plan view. In the present embodiment, the first chamfered portion 412 is a flat surface. Unlike the configuration, the first chamfered portion 412 may be a projecting curved surface in plan view.

The first side surface 413 is connected to the first front surface 411 and the first back surface 414 as illustrated in FIGS. 5 and 6. The first side surface 413 is positioned on the opposite side of the first chamfered portion 412 in the second direction x with respect to the first front surface 411. The first side surface 413 is flat and faces the other side in the second direction x. The first side surface 413 is substantially orthogonal to the first front surface 411.

The first back surface 414 faces the lower side in the thickness direction z as illustrated in FIGS. 6 and 14 to 16. Each first back surface 414 of the plurality of first side exposed portions 41A and 41C is exposed from the resin back surface 22 and is flush with the resin back surface 22. Each first back surface 414 of the plurality of first side exposed portions 41B is covered by the resin member 2.

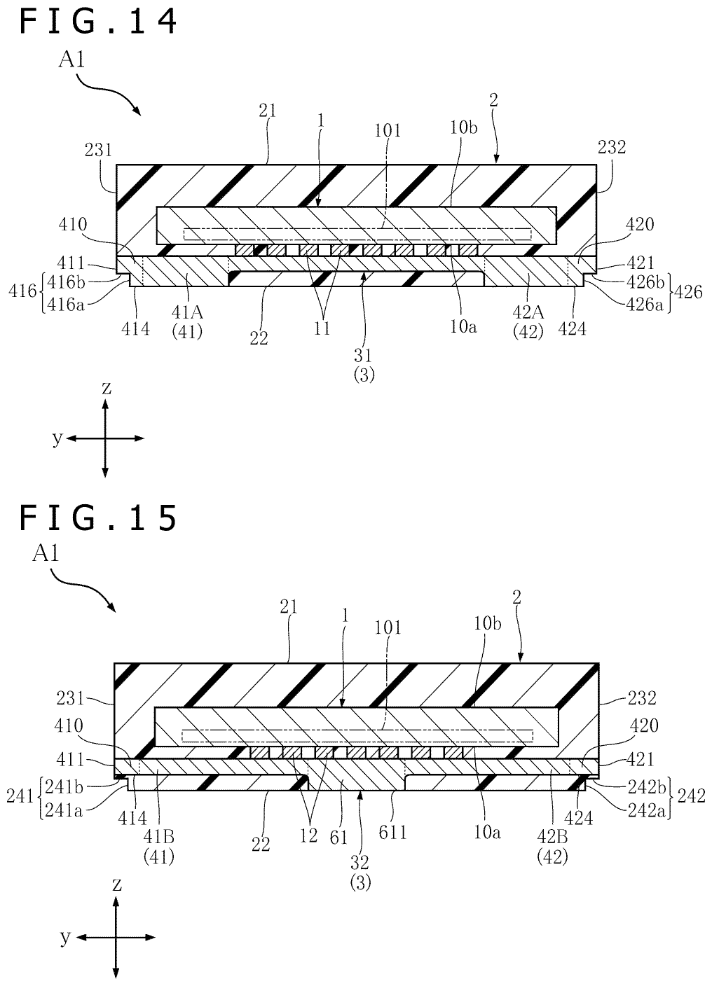

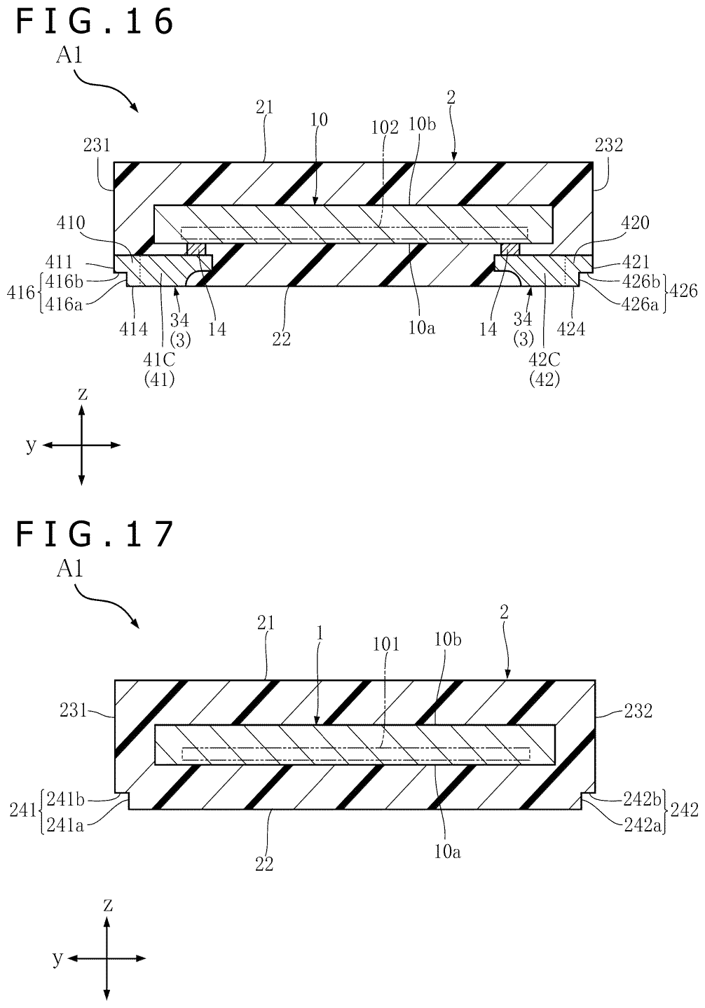

As illustrated in FIGS. 5, 6, 14, and 16, each of the plurality of first side exposed portions 41A and 41C further includes a first side recessed portion 416. The first side recessed portion 416 is recessed from the first back surface 414 and connected to the first front surface 411. The first side recessed portion 416 is connected to the first resin recessed portion 241. The surface of the first side recessed portion 416 is flush with the surface of the first resin recessed portion 241. The first side recessed portion 416 includes a first inner end surface 416a and a first link surface 416b as illustrated in FIGS. 14 and 16.

The first inner end surface 416a faces the same direction as the first front surface 411 and is substantially parallel to the first front surface 411 as illustrated in FIGS. 14 and 16. The first inner end surface 416a is positioned on the inner side of the electronic apparatus A1 with respect to the first front surface 411 in plan view (the other side in the first direction y; the side closer to the electronic part 1 in the first direction y). The first inner end surface 416a is connected to the first back surface 414. The first inner end surface 416a is flat. The first inner end surface 416a is flush with the first wall surface 241a.

The first link surface 416b is connected to the first inner end surface 416a and the first front surface 411 as illustrated in FIGS. 14 and 16. In the example illustrated in FIGS. 14 and 15, the first link surface 416b is flat and faces the lower side in the thickness direction z. Unlike the example illustrated in FIGS. 14 and 15, the first link surface 416b may be curved in a recessed shape. The first link surface 416b is flush with the first bottom surface 241b.

In each of the plurality of first side exposed portions 41A and 41C, tin plating is applied to the surfaces of the first back surface 414 and the first side recessed portion 416 (first inner end surface 416a and first link surface 416b). Note that, for example, metal plating with nickel, palladium, and gold layered in this order may be adopted instead of the tin plating.

Each of the plurality of second side exposed portions 42 is exposed from the second resin side surface 232 as illustrated in FIGS. 3, 4, and 9. The plurality of second side exposed portions 42 are arranged along the second resin side surface 232. Accordingly, the plurality of second side exposed portions 42 are arrayed in the second direction x. In the example illustrated in FIG. 3, the plurality of second side exposed portions 42 are arranged line-symmetrically to the plurality of first side exposed portions 41, about an auxiliary line L1 through the center of the electronic apparatus A1 in the first direction y. The plurality of second side exposed portions 42 include a plurality of second side exposed portions 42A, 42B, and 42C as illustrated in FIGS. 3 and 4. Each of the plurality of second side exposed portions 42A is formed on a different one of the plurality of first leads 31. Each of the plurality of second side exposed portions 42B is formed on a different one of the plurality of second leads 32. The plurality of second side exposed portions 42C are formed on the leads 34 that are arranged along the second resin side surface 232 and that are among the plurality of fourth leads 34. In the present embodiment, each interval d2 (see FIG. 4) between the second side exposed portions 42 adjacent to each other in the second direction x is, for example, equal to or greater than 50 μm but equal to or smaller than 250 μm. Particularly, the interval d2 between the second side exposed portion 42A and the second side exposed portion 42B adjacent to each other in the second direction x is short in the example illustrated in FIGS. 3 and 4, and the interval d2 is, for example, equal to or greater than 50 μm but equal to or smaller than 200 μm.

As illustrated in FIGS. 7 and 8, each of the plurality of second side exposed portions 42 (the plurality of second side exposed portions 42A to 42C) includes a second tapered portion 420. The second tapered portion 420 is a section of each second side exposed portion 42 that becomes narrower toward the second resin side surface 232 in plan view. The second tapered portion 420 includes a second front surface 421, a second chamfered portion 422, a second side surface 423, and a second back surface 424 as illustrated in FIGS. 7 and 8.

The second front surface 421 faces the same direction as the second resin side surface 232 and is flush with the second resin side surface 232 as illustrated in FIGS. 7, 8, and 14 to 16. The second front surface 421 is flat.

The second chamfered portion 422 is connected to the second front surface 421 as illustrated in FIGS. 7 and 8. The second chamfered portion 422 is formed on the one side in the second direction x in the second tapered portion 420. The second tapered portion 420 is inclined with respect to the second front surface 421 in plan view. In the present embodiment, the second tapered portion 420 is a flat surface. Unlike the configuration, the second chamfered portion 422 may be a projecting curved surface in plan view.

The second side surface 423 is connected to the second front surface 421 and the second back surface 424 as illustrated in FIGS. 7 and 8. The second side surface 423 is positioned on the opposite side of the second chamfered portion 422 in the second direction x with respect to the second front surface 421. The second side surface 423 is flat and faces the other side in the second direction x. The second side surface 423 is substantially orthogonal to the second front surface 421.

The second back surface 424 faces the lower side in the thickness direction z as illustrated in FIGS. 7, 8, and 14 to 16. Each second back surface 424 of the plurality of second side exposed portions 42A and 42C is exposed from the resin back surface 22 and is flush with the resin back surface 22. Each second back surface 424 of the plurality of second side exposed portions 42B is covered by the resin member 2.

As illustrated in FIGS. 7, 8, 14, and 16, each of the plurality of second side exposed portions 42A and 42C further includes a second side recessed portion 426. The second side recessed portion 426 is recessed from the second back surface 424 and connected to the second front surface 421. The second side recessed portion 426 is connected to the second resin recessed portion 242. The surface of the second side recessed portion 426 is flush with the surface of the second resin recessed portion 242. The second side recessed portion 426 includes a second inner end surface 426a and a second link surface 426b as illustrated in FIGS. 14 and 16.

The second inner end surface 426a faces the same direction as the second front surface 421 and is substantially parallel to the second front surface 421 as illustrated in FIGS. 14 and 16. The second inner end surface 426a is positioned on the inner side of the electronic apparatus A1 with respect to the second front surface 421 in plan view (the one side in the first direction y; the side closer to the electronic part 1 in the first direction y). The second inner end surface 426a is connected to the second back surface 424. The second inner end surface 426a is flat. The second inner end surface 426a is flush with the second wall surface 242a.

The second link surface 426b is connected to the second inner end surface 426a and the second front surface 421 as illustrated in FIGS. 14 and 16. In the example illustrated in FIGS. 14 and 16, the second link surface 426b is flat and faces the lower side in the thickness direction z. Unlike the example illustrated in FIGS. 14 and 16, the second link surface 426b may be curved in a recessed shape. The second link surface 426b is flush with the second bottom surface 242b.

In each of the plurality of second side exposed portions 42A and 42C, tin plating is applied to the surfaces of the second back surface 424 and the second side recessed portion 426 (second inner end surface 426a and second link surface 426b). Note that, for example, metal plating with nickel, palladium, and gold layered in this order may be adopted instead of the tin plating.

Each of the plurality of third side exposed portions 43 is exposed from the third resin side surface 233 as illustrated in FIGS. 3, 4, and 11. The plurality of third side exposed portions 43 are arranged along the third resin side surface 233. Accordingly, the plurality of third side exposed portions 43 are arrayed in the first direction y. Each of the plurality of third side exposed portions 43 is formed on the fifth lead 35. In the present embodiment, each interval d3 (see FIG. 4) between the third side exposed portions 43 adjacent to each other in the first direction y is, for example, equal to or greater than 100 μm but equal to or smaller than 250 μm.

As illustrated in FIGS. 5 and 7, each of the plurality of third side exposed portions 43 includes a third tapered portion 430. The third tapered portion 430 is a section of each third side exposed portion 43 that becomes narrower toward the third resin side surface 233 in plan view. The third tapered portion 430 is formed on an end portion on the outer side of the electronic apparatus A1 in plan view (the one side in the second direction x) in each third side exposed portion 43. The third tapered portion 430 includes a third front surface 431, a third chamfered portion 432, a third side surface 433, and a third back surface 434 as illustrated in FIGS. 5 and 7.

The third front surface 431 faces the same direction as the third resin side surface 233 and is flush with the third resin side surface 233 as illustrated in FIGS. 5, 7, and 13. The third front surface 431 is flat.

The third chamfered portion 432 is connected to the third front surface 431 as illustrated in FIGS. 5 and 7. The third chamfered portion 432 is formed on the one side in the first direction y in the third tapered portion 430. The third tapered portion 430 is inclined with respect to the third front surface 431 in plan view. In the present embodiment, the third tapered portion 430 is a flat surface. Unlike the configuration, the third chamfered portion 432 may be a projecting curved surface in plan view.

The third side surface 433 is connected to the third front surface 431 and the third back surface 434 as illustrated in FIGS. 5 and 7. The third side surface 433 is positioned on the opposite side of the third chamfered portion 432 in the first direction y with respect to the third front surface 431. The third side surface 433 is flat and faces the other side in the first direction y. The third side surface 433 is substantially orthogonal to the third front surface 431.

The third back surface 434 faces the lower side in the thickness direction z as illustrated in FIGS. 5, 7, and 13. The third back surface 434 is exposed from the resin back surface 22 and is flush with the resin back surface 22.

As illustrated in FIGS. 5, 7, and 13, each of the plurality of third side exposed portions 43 further includes a third side recessed portion 436. The third side recessed portion 436 is recessed from the third back surface 434 and connected to the third front surface 431. The third side recessed portion 436 is connected to the third resin recessed portion 243. The surface of the third side recessed portion 436 is flush with the surface of the third resin recessed portion 243. The third side recessed portion 436 includes a third inner end surface 436a and a third link surface 436b.

The third inner end surface 436a faces the same direction as the third front surface 431 and is substantially parallel to the third front surface 431 as illustrated in FIG. 13. The third inner end surface 436a is positioned on the inner side of the electronic apparatus A1 with respect to the third front surface 431 in plan view (the other side in the second direction x; the side closer to the electronic part 1 in the second direction x). The third inner end surface 436a is connected to the third back surface 434. The third inner end surface 436a is flat. The third inner end surface 436a is flush with the third wall surface 243a.

The third link surface 436b is connected to the third inner end surface 436a and the third front surface 431 as illustrated in FIG. 13. In the example illustrated in FIG. 13, the third link surface 436b is flat and faces the lower side in the thickness direction z. Unlike the example illustrated in FIG. 13, the third link surface 436b may be curved in a recessed shape. The third link surface 436b is flush with the third bottom surface 243b.

In each of the plurality of third side exposed portions 43, tin plating is applied to the surfaces of the third back surface 434 and the third side recessed portion 436 (third inner end surface 436a and third link surface 436b). Note that, for example, metal plating with nickel, palladium, and gold layered in this order may be adopted instead of the tin plating.

Each of the plurality of fourth side exposed portions 44 is exposed from the fourth resin side surface 234 as illustrated in FIGS. 3, 4, and 12. The plurality of fourth side exposed portions 44 are arranged along the fourth resin side surface 234. Accordingly, the plurality of fourth side exposed portions 44 are arrayed in the first direction y. Each of the plurality of fourth side exposed portions 44 is formed on a different one of the plurality of third leads 33. In the present embodiment, each interval d4 (see FIG. 4) between the fourth side exposed portions 44 adjacent to each other in the first direction y is, for example, equal to or greater than 100 μm but equal to or smaller than 250 μm.

As illustrated in FIGS. 6, 8, and 13, each of the plurality of fourth side exposed portions 44 includes a fourth tapered portion 440. The fourth tapered portion 440 is a section of each fourth side exposed portion 44 that becomes narrower toward the fourth resin side surface 234 in plan view. The fourth tapered portion 440 is formed on an end portion on the outer side of the electronic apparatus A1 in plan view (the other side in the second direction x) in each fourth side exposed portion 44. The fourth tapered portion 440 includes a fourth front surface 441, a fourth chamfered portion 442, a fourth side surface 443, and a fourth back surface 444.

The fourth front surface 441 faces the same direction as the fourth resin side surface 234 and is flush with the fourth resin side surface 234 as illustrated in FIGS. 6, 8, and 13. The fourth front surface 441 is flat.

The fourth chamfered portion 442 is connected to the fourth front surface 441 as illustrated in FIGS. 6 and 8. The fourth chamfered portion 442 is formed on the one side in the first direction y in the fourth tapered portion 440. The fourth tapered portion 440 is inclined with respect to the fourth front surface 441 in plan view. In the present embodiment, the fourth tapered portion 440 is a flat surface. Unlike the configuration, the fourth chamfered portion 442 may be a projecting curved surface in plan view.

The fourth side surface 443 is connected to the fourth front surface 441 and the fourth back surface 444 as illustrated in FIGS. 6 and 8. The fourth side surface 443 is positioned on the opposite side of the fourth chamfered portion 442 in the first direction y with respect to the fourth front surface 441. The fourth side surface 443 is flat and faces the other side in the first direction y. The fourth side surface 443 is substantially orthogonal to the fourth front surface 441.

The fourth back surface 444 faces the lower side in the thickness direction z as illustrated in FIGS. 6, 8, and 13. The fourth back surface 444 is exposed from the resin back surface 22 and is flush with the resin back surface 22.

As illustrated in FIG. 13, each of the plurality of fourth side exposed portions 44 further includes a fourth side recessed portion 446. The fourth side recessed portion 446 is recessed from the fourth back surface 444 and connected to the fourth front surface 441. The fourth side recessed portion 446 is connected to the fourth resin recessed portion 244. The surface of the fourth side recessed portion 446 is flush with the surface of the fourth resin recessed portion 244. The fourth side recessed portion 446 includes a fourth inner end surface 446a and a fourth link surface 446b as illustrated in FIGS. 6, 8, and 13.

The fourth inner end surface 446a faces the same direction as the fourth front surface 441 and is substantially parallel to the fourth front surface 441 as illustrated in FIG. 13. The fourth inner end surface 446a is positioned on the inner side of the electronic apparatus A1 with respect to the fourth front surface 441 in plan view (the one side in the second direction x; the side close to the electronic part 1 in the second direction x). The fourth inner end surface 446a is connected to the fourth back surface 444. The fourth inner end surface 446a is flat. The fourth inner end surface 446a is flush with the fourth wall surface 244a.

The fourth link surface 446b is connected to the fourth inner end surface 446a and the fourth front surface 441 as illustrated in FIG. 13. In the example illustrated in FIG. 13, the fourth link surface 446b is flat and faces the lower side in the thickness direction z. Unlike the example illustrated in FIG. 13, the fourth link surface 446b may be curved in a recessed shape. The fourth link surface 446b is flush with the fourth bottom surface 244b.

In each of the plurality of fourth side exposed portions 44, tin plating is applied to the surfaces of the fourth back surface 444 and the fourth side recessed portion 446 (fourth inner end surface 446a and fourth link surface 446b). Note that, for example, metal plating with nickel, palladium, and gold layered in this order may be adopted instead of the tin plating.

The first corner exposed portion 51, the second corner exposed portion 52, the third corner exposed portion 53, and the fourth corner exposed portion 54 are arranged near the four corners of the resin member 2 in plan view as illustrated in FIGS. 3 and 4. Each of the first corner exposed portion 51, the second corner exposed portion 52, the third corner exposed portion 53, and the fourth corner exposed portion 54 is formed on a different one of the plurality of sixth leads 36. In the present embodiment, the first corner exposed portion 51, the second corner exposed portion 52, the third corner exposed portion 53, and the fourth corner exposed portion 54 are not electrically connected to the electronic part 1. Unlike the configuration, at least one of the first corner exposed portion 51, the second corner exposed portion 52, the third corner exposed portion 53, and the fourth corner exposed portion 54 may be electrically connected to the electronic part 1.

The first corner exposed portion 51 and the second corner exposed portion 52 are arranged on opposite sides across the plurality of first side exposed portions 41 as illustrated in FIGS. 3 and 4. As illustrated in FIGS. 3 and 4, the first corner exposed portion 51 is arranged on the one side in the second direction x with respect to the plurality of first side exposed portions 41, and the second corner exposed portion 52 is arranged on the other side in the second direction x with respect to the plurality of first side exposed portions 41.

The first corner exposed portion 51 is exposed from the resin back surface 22 and is also exposed from each of the first resin side surface 231 and the third resin side surface 233 as illustrated in FIGS. 4 and 5. The first corner exposed portion 51 includes two end surfaces 511 and 512, two side surfaces 513 and 514, a chamfered portion 515, a back surface 516, and two recessed portions 517 and 518 as illustrated in FIGS. 5, 10, and 11.

Each of the two end surfaces 511 and 512 is exposed from the resin member 2. Each of the two end surfaces 511 and 512 is flat. The end surface 511 faces the same direction as the first resin side surface 231 and is flush with the first resin side surface 231. The end surface 512 faces the same direction as the third resin side surface 233 and is flush with the third resin side surface 233.

Each of the two side surfaces 513 and 514 is covered by the resin member 2. The side surface 513 faces the side opposite the end surface 511 in the first direction y. The side surface 513 is connected to the end surface 512. The side surface 513 faces the plurality of third side exposed portions 43. The side surface 514 faces the side opposite the end surface 512 in the second direction x. The side surface 514 is connected to the end surface 511. The side surface 514 faces the plurality of first side exposed portions 41.

The chamfered portion 515 is connected to the end surface 511 and the end surface 512. The chamfered portion 515 is a flat surface. The chamfered portion 515 is inclined with respect to each of the end surface 511 and the end surface 512 in plan view. The chamfered portion 515 is covered by the resin member 2.

The back surface 516 faces the lower side in the thickness direction z. The back surface 516 is exposed from the resin back surface 22 and is flush with the resin back surface 22. The back surface 516 is connected to the two side surfaces 513 and 514 and the two recessed portions 517 and 518.

The recessed portion 517 is recessed from the back surface 516 and connected to the end surface 511. The surface of the recessed portion 517 is flush with the surface of the first resin recessed portion 241 of the resin member 2. The recessed portion 517 includes a recessed portion side surface 517a and a recessed portion bottom surface 517b. The recessed portion side surface 517a is connected to the back surface 516. The recessed portion side surface 517a is flat. The recessed portion side surface 517a faces the same direction as the end surface 511. The recessed portion side surface 517a is positioned on the inner side of the electronic apparatus A1 with respect to the end surface 511 in plan view (the other side in the first direction y). The recessed portion side surface 517a is flush with the first wall surface 241a of the first resin recessed portion 241. The recessed portion bottom surface 517b is connected to the end surface 511 and the recessed portion side surface 517a. In the present embodiment, the recessed portion bottom surface 517b is flat and faces the lower side in the thickness direction z. The recessed portion bottom surface 517b is flush with the first bottom surface 241b of the first resin recessed portion 241.

The recessed portion 518 is recessed from the back surface 516 and connected to the end surface 512. The surface of the recessed portion 518 is flush with the surface of the third resin recessed portion 243 of the resin member 2. The recessed portion 518 includes a recessed portion side surface 518a and a recessed portion bottom surface 518b. The recessed portion side surface 518a is connected to the back surface 516. The recessed portion side surface 518a is flat. The recessed portion side surface 518a faces the same direction as the end surface 512. The recessed portion side surface 518a is positioned on the inner side of the electronic apparatus A1 with respect to the end surface 512 in plan view (the other side in the second direction x). The recessed portion side surface 518a is flush with the third wall surface 243a of the third resin recessed portion 243. The recessed portion bottom surface 518b is connected to the end surface 512 and the recessed portion side surface 518a. In the present embodiment, the recessed portion bottom surface 518b is flat and faces the lower side in the thickness direction z. The recessed portion bottom surface 518b is flush with the third bottom surface 243b of the third resin recessed portion 243.

Tin plating is applied to the back surface 516, the surface of the recessed portion 517 (recessed portion side surface 517a and recessed portion bottom surface 517b ), and the surface of the recessed portion 518 (recessed portion side surface 518a and recessed portion bottom surface 518b) in the first corner exposed portion 51. Note that, for example, metal plating with nickel, palladium, and gold layered in this order may be adopted instead of the tin plating.

The second corner exposed portion 52 is exposed from the resin back surface 22 and is also exposed from each of the first resin side surface 231 and the fourth resin side surface 234 as illustrated in FIGS. 4 and 6. The second corner exposed portion 52 includes two end surfaces 521 and 522, two side surfaces 523 and 524, two chamfered portions 525A and 525B, a back surface 526, and two recessed portions 527 and 528 as illustrated in FIGS. 4, 6, 10, and 12.

Each of the two end surfaces 521 and 522 is exposed from the resin member 2. The end surface 521 is flat. The end surface 521 faces the same direction as the first resin side surface 231 and is flush with the first resin side surface 231. The end surface 522 is flat. The end surface 522 faces the same direction as the fourth resin side surface 234 and is flush with the fourth resin side surface 234.

Each of the two side surfaces 523 and 524 is covered by the resin member 2. The side surface 523 faces the side opposite the end surface 521 in the first direction y. The side surface 523 is connected to the end surface 522. The side surface 523 faces the plurality of fourth side exposed portions 44. The side surface 524 faces the side opposite the end surface 522 in the second direction x. The side surface 524 faces the plurality of first side exposed portions 41.

The chamfered portion 525A is connected to each of the two end surfaces 521 and 522. The chamfered portion 525A is a flat surface. The chamfered portion 525A is inclined with respect to both the two end surfaces 521 and 522 in plan view. The chamfered portion 525A is covered by the resin member 2.

The chamfered portion 525B is connected to the end surface 521 and the side surface 524. The chamfered portion 525B is a flat surface. The chamfered portion 525B is inclined with respect to both the end surface 521 and the side surface 524 in plan view. The chamfered portion 525B is covered by the resin member 2.

The back surface 526 faces the lower side in the thickness direction z. The back surface 526 is exposed from the resin back surface 22 and is flush with the resin back surface 22. The back surface 526 is connected to the two side surfaces 523 and 524 and the two recessed portions 527 and 528.

The recessed portion 527 is recessed from the back surface 526 and connected to the end surface 521. The recessed portion 527 is flush with the first resin recessed portion 241 of the resin member 2. The recessed portion 527 includes a recessed portion side surface 527a and a recessed portion bottom surface 527b. The recessed portion side surface 527a is connected to the back surface 526. The recessed portion side surface 527a is flat. The recessed portion side surface 527a faces the same direction as the end surface 521. The recessed portion side surface 527a is positioned on the inner side of the electronic apparatus A1 with respect to the end surface 521 in plan view (the other side in the first direction y). The recessed portion side surface 527a is flush with the first wall surface 241a of the first resin recessed portion 241. The recessed portion bottom surface 527b is connected to the end surface 521 and the recessed portion side surface 527a. In the present embodiment, the recessed portion bottom surface 527b is flat and faces the lower side in the thickness direction z. The recessed portion bottom surface 527b is flush with the first bottom surface 241b of the first resin recessed portion 241.

The recessed portion 528 is recessed from the back surface 526 and connected to the end surface 522. The surface of the recessed portion 528 is flush with the surface of the fourth resin recessed portion 244 of the resin member 2. The recessed portion 528 includes a recessed portion side surface 528a and a recessed portion bottom surface 528b. The recessed portion side surface 528a is connected to the back surface 526. The recessed portion side surface 528a is flat. The recessed portion side surface 528a faces the same direction as the end surface 522. The recessed portion side surface 528a is positioned on the inner side of the electronic apparatus A1 with respect to the end surface 522 in plan view (the one side in the second direction x). The recessed portion side surface 528a is flush with the fourth wall surface 244a of the fourth resin recessed portion 244. The recessed portion bottom surface 528b is connected to the end surface 522 and the recessed portion side surface 528a. In the present embodiment, the recessed portion bottom surface 528b is flat and faces the lower side in the thickness direction z. The recessed portion bottom surface 528b is flush with the fourth bottom surface 244b of the fourth resin recessed portion 244.

Tin plating is applied to the end surface 522, the surface of the recessed portion 527 (recessed portion side surface 527a and recessed portion bottom surface 527b, and the surface of the recessed portion 528 (recessed portion side surface 528a and recessed portion bottom surface 528b) in the second corner exposed portion 52. Note that, for example, metal plating with nickel, palladium, and gold layered in this order may be adopted instead of the tin plating.

The third corner exposed portion 53 and the fourth corner exposed portion 54 are arranged on the opposite sides across the plurality of second side exposed portions 42 in the second direction x as illustrated in FIGS. 3 and 4. As illustrated in FIGS. 3 and 4, the third corner exposed portion 53 is arranged on the one side in the second direction x with respect to the plurality of second side exposed portions 42, and the fourth corner exposed portion 54 is arranged on the other side in the second direction x with respect to the plurality of second side exposed portions 42.

The third corner exposed portion 53 is exposed from the resin back surface 22 and is also exposed from each of the second resin side surface 232 and the third resin side surface 233 as illustrated in FIGS. 4 and 7. The third corner exposed portion 53 includes two end surfaces 531 and 532, two side surfaces 533 and 534, two chamfered portions 535A and 535B, a back surface 536, and two recessed portions 537 and 538 as illustrated in FIGS. 4, 7, 9 and 11.

Each of the two end surfaces 531 and 532 is exposed from the resin member 2. Each of the two end surfaces 531 and 532 is flat. The end surface 531 faces the same direction as the second resin side surface 232 and is flush with the second resin side surface 232. The end surface 532 faces the same direction as the third resin side surface 233 and is flush with the third resin side surface 233.

Each of the two side surfaces 533 and 534 is covered by the resin member 2. Each of the two side surfaces 533 and 534 is flat. The two side surfaces 533 and 534 are orthogonal to each other. The side surface 533 faces the side opposite the end surface 531 in the first direction y. The side surface 533 faces the plurality of third side exposed portions 43. The side surface 534 faces the side opposite the end surface 532 in the second direction x. The side surface 534 faces the plurality of second side exposed portions 42.

The chamfered portion 535A is connected to the two end surfaces 531 and 532. The chamfered portion 535A is a flat surface. The chamfered portion 535A is inclined with respect to both the two end surfaces 531 and 532 in plan view. The chamfered portion 535A is covered by the resin member 2.

The chamfered portion 535B is connected to the end surface 532 and the side surface 533. The chamfered portion 535B is a flat surface. The chamfered portion 535B is inclined with respect to both the end surface 532 and the side surface 533 in plan view. The chamfered portion 535B is covered by the resin member 2.

The back surface 536 faces the lower side in the thickness direction z. The back surface 536 is exposed from the resin back surface 22 and is flush with the resin back surface 22. The back surface 536 is connected to the two side surfaces 533 and 534 and the two recessed portions 537 and 538.

The recessed portion 537 is recessed from the back surface 536 and connected to the end surface 531. The surface of the recessed portion 537 is flush with the surface of the second resin recessed portion 242 of the resin member 2. The recessed portion 537 includes a recessed portion side surface 537a and a recessed portion bottom surface 537b. The recessed portion side surface 537a is connected to the back surface 536. The recessed portion side surface 537a is flat. The recessed portion side surface 537a faces the same direction as the end surface 531. The recessed portion side surface 537a is positioned on the inner side of the electronic apparatus A1 with respect to the end surface 531 in plan view (the one side in the first direction y). The recessed portion side surface 537a is flush with the second wall surface 242a of the second resin recessed portion 242. The recessed portion bottom surface 537b is connected to the end surface 531 and the recessed portion side surface 537a. In the present embodiment, the recessed portion bottom surface 537b is flat and faces the lower side in the thickness direction z. The recessed portion bottom surface 537b is flush with the second bottom surface 242b of the second resin recessed portion 242.

The recessed portion 538 is recessed from the back surface 536 and connected to the end surface 532. The surface of the recessed portion 538 is flush with the surface of the third resin recessed portion 243 of the resin member 2. The recessed portion 538 includes a recessed portion side surface 538a and a recessed portion bottom surface 538b. The recessed portion side surface 538a is connected to the back surface 536. The recessed portion side surface 538a is flat. The recessed portion side surface 538a faces the same direction as the end surface 532. The recessed portion side surface 538a is positioned on the inner side of the electronic apparatus A1 with respect to the end surface 532 in plan view (the other side in the second direction x). The recessed portion side surface 538a is flush with the third wall surface 243a of the third resin recessed portion 243. The recessed portion bottom surface 538b is connected to the end surface 532 and the recessed portion side surface 538a. In the present embodiment, the recessed portion bottom surface 538b is flat and faces the lower side in the thickness direction z. The recessed portion bottom surface 538b is flush with the third bottom surface 243b of the third resin recessed portion 243.

Tin plating is applied to the back surface 536, the surface of the recessed portion 537 (recessed portion side surface 537a and recessed portion bottom surface 537b, and the surface of the recessed portion 538 (recessed portion side surface 538a and recessed portion bottom surface 538b) in the third corner exposed portion 53. Note that, for example, metal plating with nickel, palladium, and gold layered in this order may be adopted instead of the tin plating.

The fourth corner exposed portion 54 is exposed from the resin back surface 22 and is also exposed from each of the second resin side surface 232 and the fourth resin side surface 234 as illustrated in FIGS. 4 and 8. The fourth corner exposed portion 54 includes two end surfaces 541 and 542, two side surfaces 543 and 544, two chamfered portions 545A and 545B, a back surface 546, and two recessed portions 547 and 548 as illustrated in FIGS. 4, 8, 9, and 12.

Each of the two end surfaces 541 and 542 is exposed from the resin member 2. Each of the two end surfaces 541 and 542 is flat. The end surface 541 faces the same direction as the second resin side surface 232 and is flush with the second resin side surface 232. The end surface 542 faces the same direction as the fourth resin side surface 234 and is flush with the fourth resin side surface 234.

Each of the two side surfaces 543 and 544 is covered by the resin member 2. The side surface 543 faces the side opposite the end surface 541 in the first direction y. The side surface 543 faces the plurality of fourth side exposed portions 44. The side surface 544 faces the side opposite the end surface 542 in the second direction x. The side surface 544 faces the plurality of second side exposed portions 42. The two side surfaces 543 and 544 are orthogonal to each other.

The chamfered portion 545A is connected to the end surface 541 and the side surface 544. The chamfered portion 545A is a flat surface. The chamfered portion 545A is inclined with respect to both the end surface 541 and the side surface 544 in plan view. The chamfered portion 545A is covered by the resin member 2.

The chamfered portion 545B is connected to the end surface 542 and the side surface 543. The chamfered portion 545B is a flat surface. The chamfered portion 545B is inclined with respect to both the end surface 542 and the side surface 543 in plan view. The chamfered portion 545B is covered by the resin member 2.

The back surface 546 faces the lower side in the thickness direction z. The back surface 546 is exposed from the resin back surface 22 and is flush with the resin back surface 22. The back surface 546 is connected to the two side surfaces 543 and 544 and the two recessed portions 547 and 548.

The recessed portion 547 is recessed from the back surface 546 and connected to the end surface 541. The surface of the recessed portion 547 is flush with the surface of the second resin recessed portion 242 of the resin member 2. The recessed portion 547 includes a recessed portion side surface 547a and a recessed portion bottom surface 547b. The recessed portion side surface 547a is connected to the back surface 546. The recessed portion side surface 547a is flat. The recessed portion side surface 547a faces the same direction as the end surface 541. The recessed portion side surface 547a is positioned on the inner side of the electronic apparatus A1 with respect to the end surface 541 in plan view (the one side in the first direction y). The recessed portion side surface 547a is flush with the second wall surface 242a of the second resin recessed portion 242. The recessed portion bottom surface 547b is connected to the end surface 541 and the recessed portion side surface 547a. In the present embodiment, the recessed portion bottom surface 547b is flat and faces the lower side in the thickness direction z. The recessed portion bottom surface 547b is flush with the second bottom surface 242b of the second resin recessed portion 242.

The recessed portion 548 is recessed from the back surface 546 and connected to the end surface 542. The surface of the recessed portion 548 is flush with the surface of the fourth resin recessed portion 244 of the resin member 2. The recessed portion 548 includes a recessed portion side surface 548a and a recessed portion bottom surface 548b. The recessed portion side surface 548a is connected to the back surface 546. The recessed portion side surface 548a is flat. The recessed portion side surface 548a faces the same direction as the end surface 542. The recessed portion side surface 548a is positioned on the inner side of the electronic apparatus A1 with respect to the end surface 542 in plan view (the one side in the second direction x). The recessed portion side surface 548a is flush with the fourth wall surface 244a of the fourth resin recessed portion 244. The recessed portion bottom surface 548b is connected to the end surface 542 and the recessed portion side surface 548a. In the present embodiment, the recessed portion bottom surface 548b is flat and faces the lower side in the thickness direction z. The recessed portion bottom surface 548b is flush with the fourth bottom surface 244b of the fourth resin recessed portion 244.

Tin plating is applied to the back surface 546, the surface of the recessed portion 547 (recessed portion side surface 547a and recessed portion bottom surface 547b, and the surface of the recessed portion 548 (recessed portion side surface 548a and recessed portion bottom surface 548b) in the fourth corner exposed portion 54. Note that, for example, metal plating with nickel, palladium, and gold layered in this order may be adopted instead of the tin plating.

Each of the plurality of back surface exposed portions 61 is not exposed from any of the first resin side surface 231, the second resin side surface 232, the third resin side surface 233, and the fourth resin side surface 234 and is exposed from only the resin back surface 22 as illustrated in FIG. 4. Each of the plurality of back surface exposed portions 61 is formed on a different one of the plurality of second leads 32.

Each of the plurality of back surface exposed portions 61 includes a back surface 611 as illustrated in FIGS. 4 and 15. The back surface 611 faces the lower side in the thickness direction z. The back surface 611 is exposed from the resin back surface 22 and is flush with the resin back surface 22.

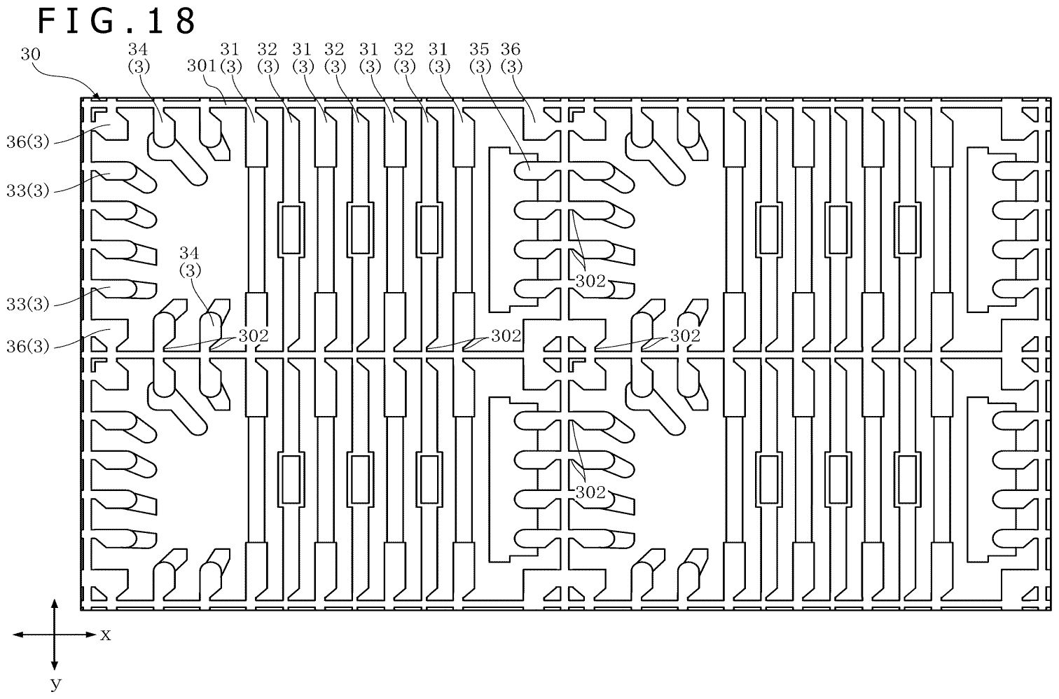

Next, a manufacturing method of the electronic apparatus A1 will be described with reference to FIGS. 18 to 25. FIGS. 18, 19, 21, 22, and 24 are bottom views of main parts illustrating one step of the manufacturing method of the electronic apparatus A1. FIGS. 20, 23, and 25 are cross-sectional views of main parts illustrating one step of the manufacturing method of the electronic apparatus A1, corresponding to a cross section of the electronic apparatus A1 illustrated in FIG. 14.

First, a lead frame 30 illustrated in FIG. 18 is prepared. The lead frame 30 has a size that allows a plurality of electronic apparatuses A1 to be manufactured. A part of the lead frame 30 corresponding to four electronic apparatuses A1 is enlarged in FIG. 18. The lead frame 30 is formed by application of a cutting process, an etching process, and other processes to a flat plate containing copper or a copper alloy as a constituent material. The lead frame 30 includes a section that is to subsequently be formed into the plurality of leads 3, and the plurality of leads 3 are connected to each other at a frame portion 301. A cutout 302 is appropriately formed at a part where adjacent leads 3 are connected to each other. In the example illustrated in FIG. 18, the cutout 302 is trapezoidal in plan view. The cutout 302 is formed, for example, on the one side in the second direction x at each part where the first leads 31 adjacent to each other in the first direction y are connected to each other, each part where the second leads 32 adjacent to each other in the first direction y are connected to each other, and each part where the fourth leads 34 adjacent to each other in the first direction y are connected to each other. The cutout 302 is also formed on the one side in the first direction y at each part where the third lead 33 and the fifth lead 35 adjacent to each other in the second direction x are connected to each other. The cutout 302 is also appropriately formed at each part where the sixth leads 36 adjacent to each other in the first direction y are connected to each other and each part where the sixth leads 36 adjacent to each other in the second direction x are connected to each other. The shape of the lead frame 30 (particularly, the frame portion 301) is not limited to the example illustrated in FIG. 18.

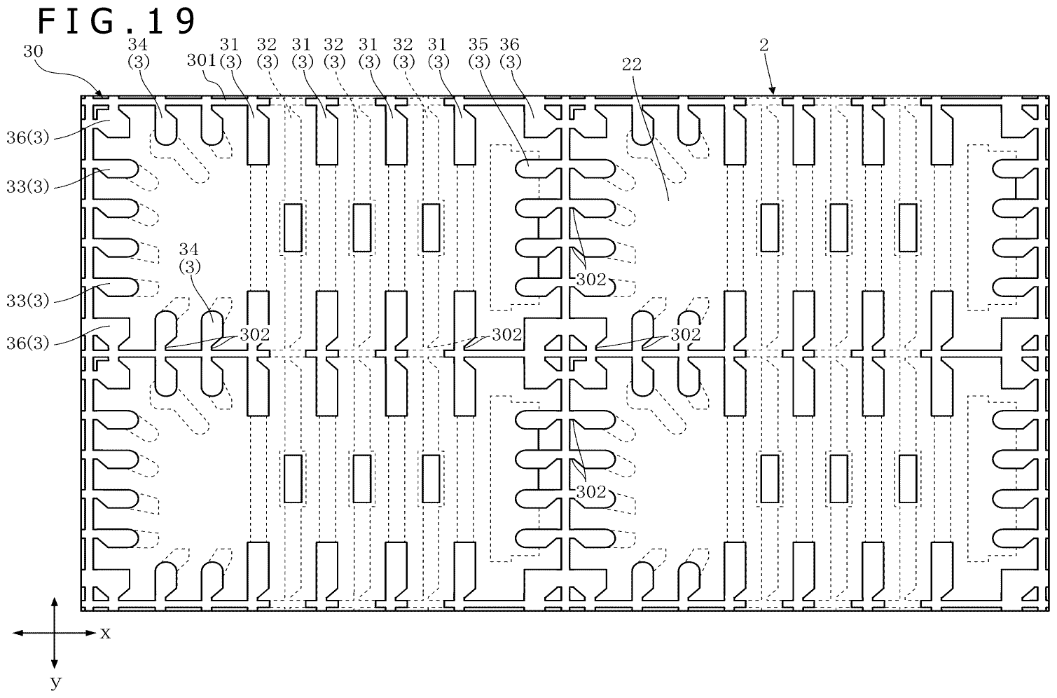

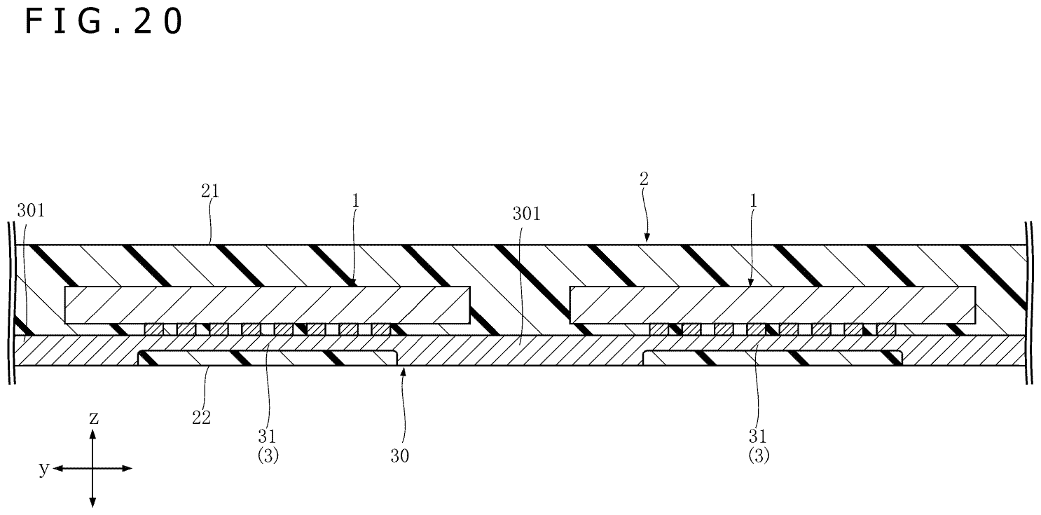

Next, the electronic part 1 is mounted on the lead frame 30, and the resin member 2 is formed, as illustrated in FIGS. 19 and 20. The resin member 2 is formed by, for example, molding. The resin member 2 covers the electronic part 1 and partially covers the lead frame 30. Part of the lead frame 30 is exposed from the resin back surface 22 as illustrated in FIGS. 19 and 20.

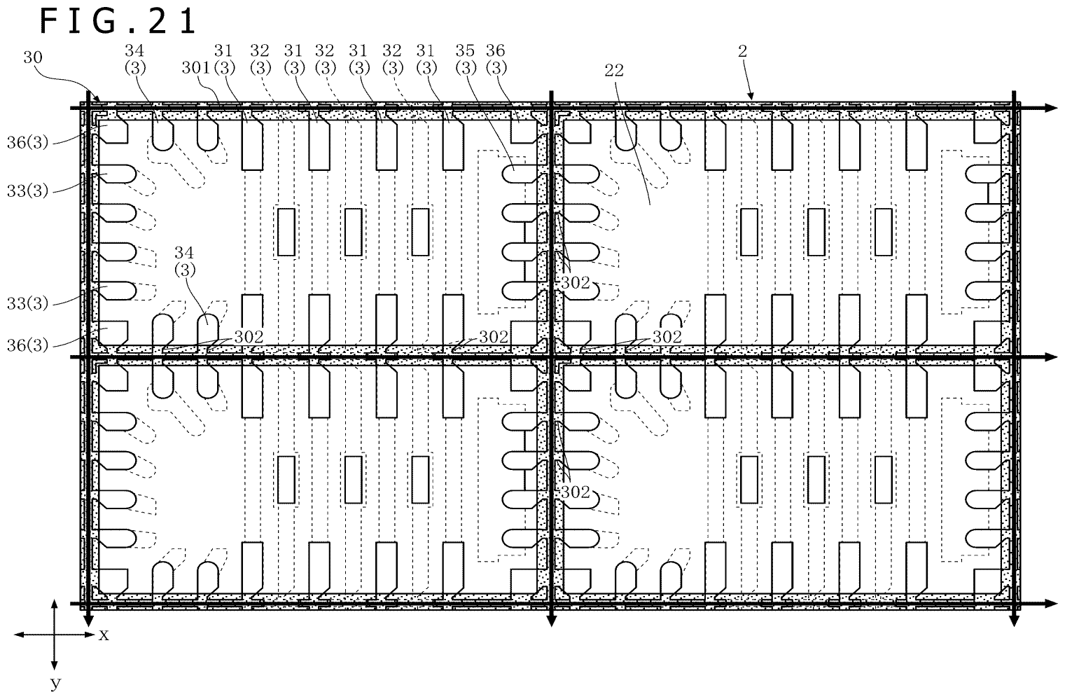

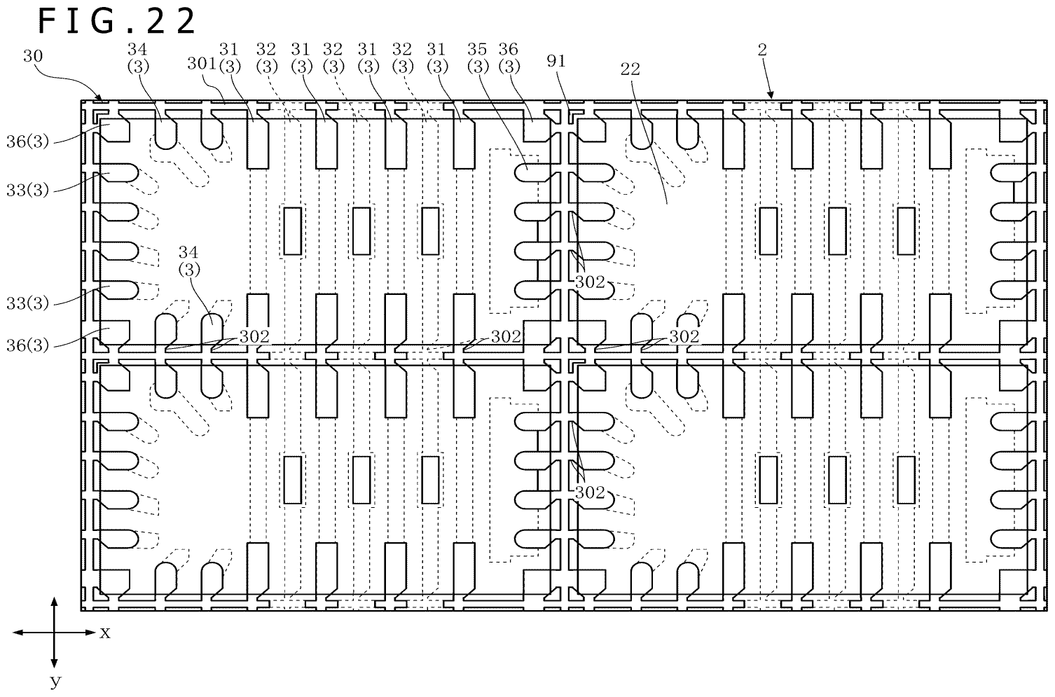

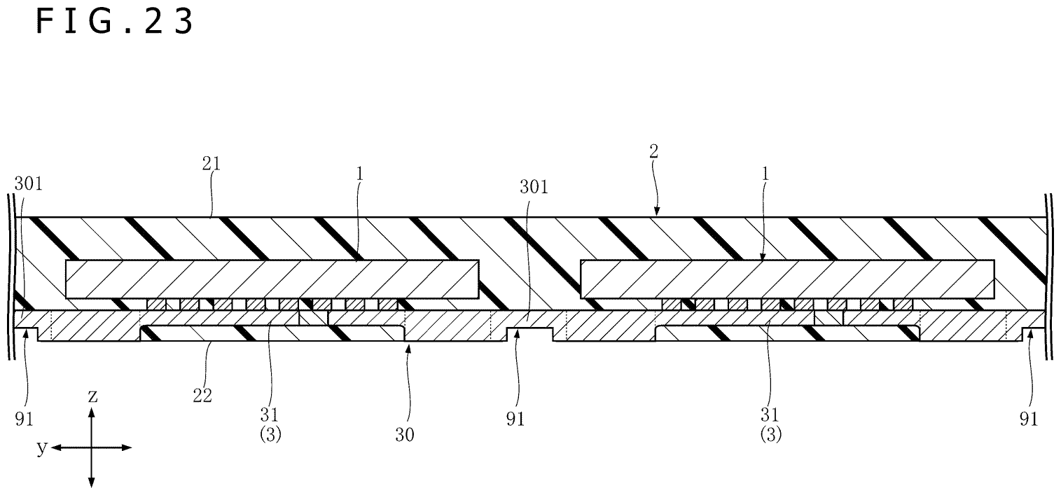

Next, half-cut dicing is performed as illustrated in FIG. 21. Dots in FIG. 21 represent regions subject to the half-cut dicing. In the half-cut dicing, a dicing blade is moved in, for example, a direction of an arrow illustrated in FIG. 21 (first dicing direction). In the first dicing direction along the first direction y, the direction from the other side in the first direction y to the one side in the first direction y (that is, the direction from the side without the cutout 302 to the side with the cutout 302) is the direction of travel of the dicing blade. In the first dicing direction along the second direction x, the direction from the other side in the second direction x to the one side in the second direction x (that is, direction from the side without the cutout 302 to the side with the cutout 302) is the direction of travel of the dicing blade. As a result of the half-cut dicing, grooves 91 in a grid pattern in plan view are formed across the resin member 2 and the lead frame 30 as illustrated in FIGS. 22 and 23. Note that a process for removal of metal burrs may be executed as necessary after the half-cut dicing.

Next, a plating process is applied to the surface of the lead frame 30 exposed from the resin back surface 22 and the grooves 91. In the present embodiment, tin plating is formed, for example.

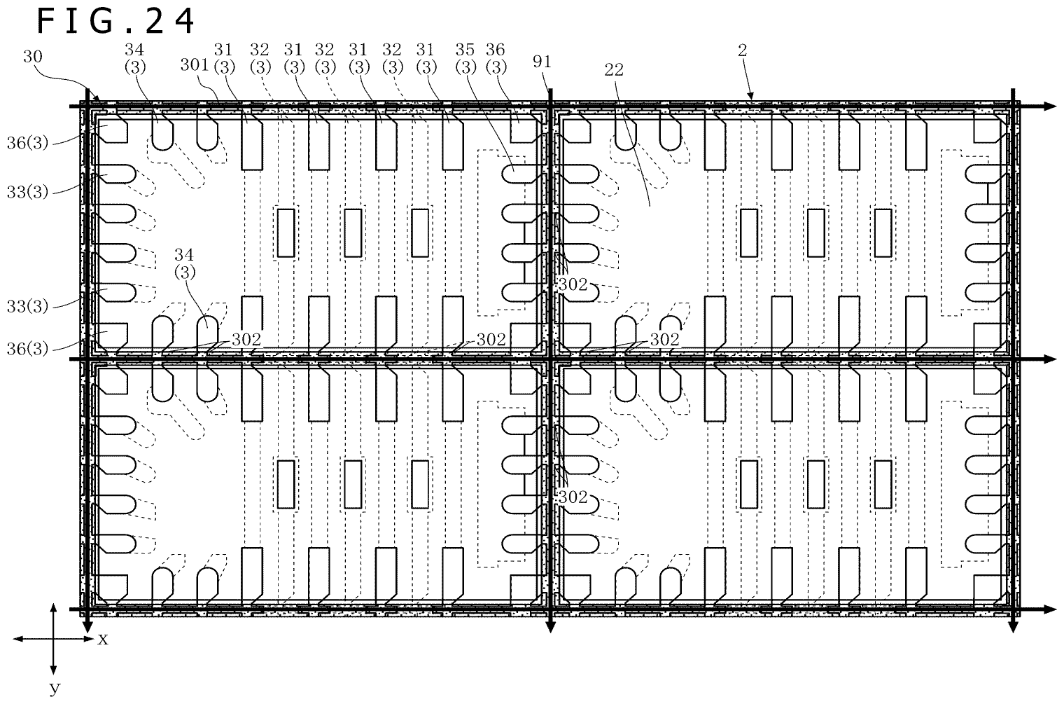

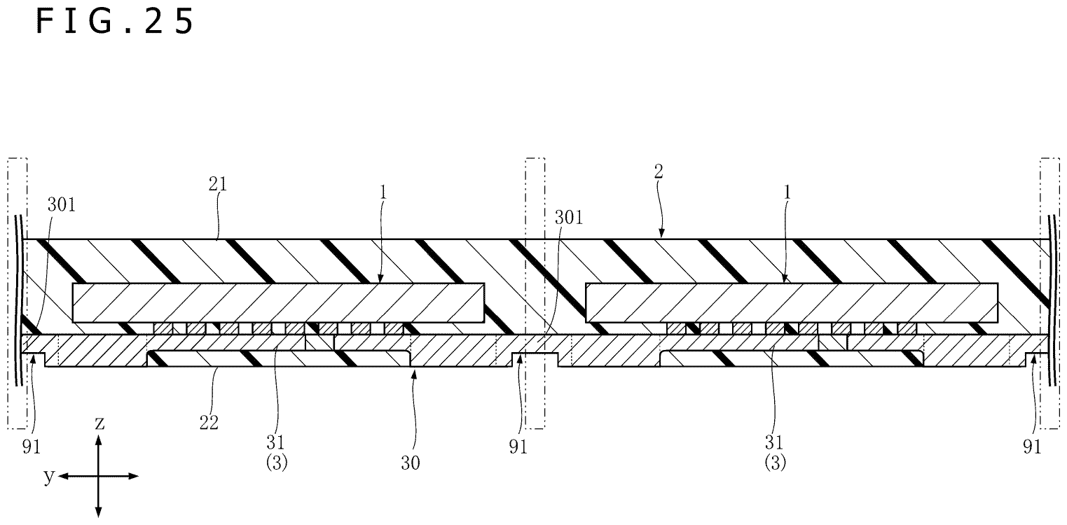

Next, full-cut dicing (cutting) is performed to form pieces of electronic parts 1 as illustrated in FIGS. 24 and 25. Dots in FIG. 24 represent regions subject to the full-cut dicing. In the full-cut dicing, a dicing blade is moved in, for example, a direction of an arrow illustrated in FIG. 24 (second dicing direction). In the second dicing direction along the first direction y, the direction from the other side in the first direction y to the one side in the first direction y (that is, the direction from the side without the cutout 302 to the side with the cutout 302) is the direction of travel of the dicing blade. In the second dicing direction along the second direction x, the direction from the other side in the second direction x to the one side in the second direction x (that is, the direction from the side without the cutout 302 to the side with the cutout 302) is the direction of travel of the dicing blade. The dicing blade used in the full-cut dicing is thinner than the dicing blade used in the half-cut dicing.

A plurality of electronic apparatuses A1 illustrated in FIGS. 1 to 17 are manufactured through the steps described above. Note that the manufacturing method of the electronic apparatus A1 is an example, and the manufacturing method is not limited to the example.

Effects of the electronic apparatus A1 are as follows.

The electronic apparatus A1 includes the plurality of first side exposed portions 41. The plurality of first side exposed portions 41 are arranged along the first resin side surface 231, and each of the plurality of first side exposed portions 41 is exposed from the first resin side surface 231. Each of the plurality of first side exposed portions 41 includes the first tapered portion 410 that becomes narrower toward the first resin side surface 231 as viewed in the thickness direction z, and the first tapered portion 410 faces the same direction as the first resin side surface 231 in the first direction y and includes the first front surface 411 flush with the first resin side surface 231. Note that the first front surface 411 is formed during dicing in the manufacturing steps of the electronic apparatus A1. According to the configuration, the distance between the first front surfaces 411 of the first side exposed portions 41 adjacent to each other in the second direction x is larger than that when the first tapered portions 410 are not formed. As a result, even if metal burrs are generated in the manufacturing of the electronic apparatus A1 (in the full-cut dicing), short circuit of a plurality of first side exposed portions 41 is suppressed in the electronic apparatus A1. Hence, compared to the configuration in which the first tapered portion 410 is not formed on each first side exposed portion 41, the electronic apparatus A1 can suppress the short circuit of a plurality of first side exposed portions 41 and reduce the intervals between the leads 3 adjacent to each other. That is, the electronic apparatus A1 can be downsized while short circuit of the leads 3 adjacent to each other is suppressed. Furthermore, the first tapered portion 410 is formed on each first side exposed portion 41, and hence, the area of the lead 3 (each first side exposed portion 41) cut in the full-cut dicing is small. This can also reduce the size (length) of metal burrs even if metal burrs are generated.

The electronic apparatus A1 includes the plurality of second side exposed portions 42. The plurality of second side exposed portions 42 are arranged along the second resin side surface 232, and each of the plurality of second side exposed portions 42 is exposed from the second resin side surface 232. Each of the plurality of second side exposed portions 42 includes the second tapered portion 420 that becomes narrower toward the second resin side surface 232 as viewed in the thickness direction z, and the second tapered portion 420 faces the same direction as the second resin side surface 232 in the first direction y and includes the second front surface 421 flush with the second resin side surface 232. Note that the second front surface 421 is formed during dicing in the manufacturing steps of the electronic apparatus A1. According to the configuration, the electronic apparatus A1 can suppress short circuit of a plurality of second side exposed portions 42 and reduce the intervals between the leads 3 adjacent to each other compared to the configuration in which the second tapered portion 420 is not formed on each second side exposed portion 42, as with the first side exposed portion 41. That is, the electronic apparatus A1 can be downsized while the short circuit of the leads 3 adjacent to each other is suppressed. In addition, short circuit of the leads 3 can be suppressed in both the first resin side surface 231 and the second resin side surface 232 separated in the first direction y. Furthermore, the second tapered portion 420 is formed on each second side exposed portion 42, and hence, the area of the lead 3 (each second side exposed portion 42) cut in the full-cut dicing is small. This can also reduce the size (length) of metal burrs even if metal burrs are generated.

The electronic apparatus A1 includes the plurality of third side exposed portions 43 arranged along the third resin side surface 233, and each third side exposed portion 43 includes the third tapered portion 430 that becomes narrower toward the third resin side surface 233 in plan view. According to the configuration, the electronic apparatus A1 can suppress short circuit of the plurality of third side exposed portions 43 and reduce the intervals between the leads 3 adjacent to each other compared to the configuration in which the third tapered portion 430 is not formed on each third side exposed portion 43, as with the first side exposed portion 41 and the second side exposed portion 42. That is, the electronic apparatus A1 can be downsized while the short circuit of the leads 3 adjacent to each other is suppressed. Furthermore, the third tapered portion 430 is formed on each third side exposed portion 43, and hence, the area of the lead 3 (each third side exposed portion 43) cut in the full-cut dicing is small. This can also reduce the size (length) of metal burrs even if metal burrs are generated.

The electronic apparatus A1 includes the plurality of fourth side exposed portions 44 arranged along the fourth resin side surface 234, and each fourth side exposed portion 44 includes the fourth tapered portion 440 that becomes narrower toward the fourth resin side surface 234 in plan view. According to the configuration, the electronic apparatus A1 can suppress short circuit of a plurality of fourth side exposed portions 44 and reduce the intervals between the leads 3 adjacent to each other compared to the configuration in which the fourth tapered portion 440 is not formed on each fourth side exposed portion 44, as with the first side exposed portion 41 and the second side exposed portion 42. That is, the electronic apparatus A1 can be downsized while the short circuit of the leads 3 adjacent to each other is suppressed. Furthermore, the fourth tapered portion 440 is formed on each fourth side exposed portion 44, and hence, the area of the lead 3 (each fourth side exposed portion 44) cut in the full-cut dicing is small. This can also reduce the size (length) of metal burrs even if metal burrs are generated.

In the electronic apparatus A1, the first tapered portion 410 includes the first front surface 411 and the first chamfered portion 412. The first chamfered portion 412 is arranged on the one side in the second direction x with respect to the first front surface 411. The second tapered portion 420 includes the second front surface 421 and the second chamfered portion 422. The second chamfered portion 422 is arranged on the one side in the second direction x with respect to the second front surface 421. The metal burrs that may be generated in the manufacturing of the electronic apparatus A1 (in the full-cut dicing) often protrude in the direction of travel in the second dicing direction during the full-cut dicing. As such, the first chamfered portion 412 is formed on the front side in the direction of travel in the second dicing direction along the second direction x in each first side exposed portion 41 in the electronic apparatus A1. The second chamfered portion 422 is formed on the front side in the direction of travel in the second dicing direction along the second direction x in each second side exposed portion 42. Accordingly, the second dicing direction is taken into account to form each first tapered portion 410 and each second tapered portion 420 in the electronic apparatus A1, and this can suppress both the short circuit of the first side exposed portions 41 adjacent to each other and the short circuit of the second side exposed portions 42 adjacent to each other. The same applies to the third chamfered portion 432 included in the third tapered portion 430 and the fourth chamfered portion 442 included in the fourth tapered portion 440.

Next, electronic apparatuses A2 to A4 according to modifications of the first embodiment will be described.

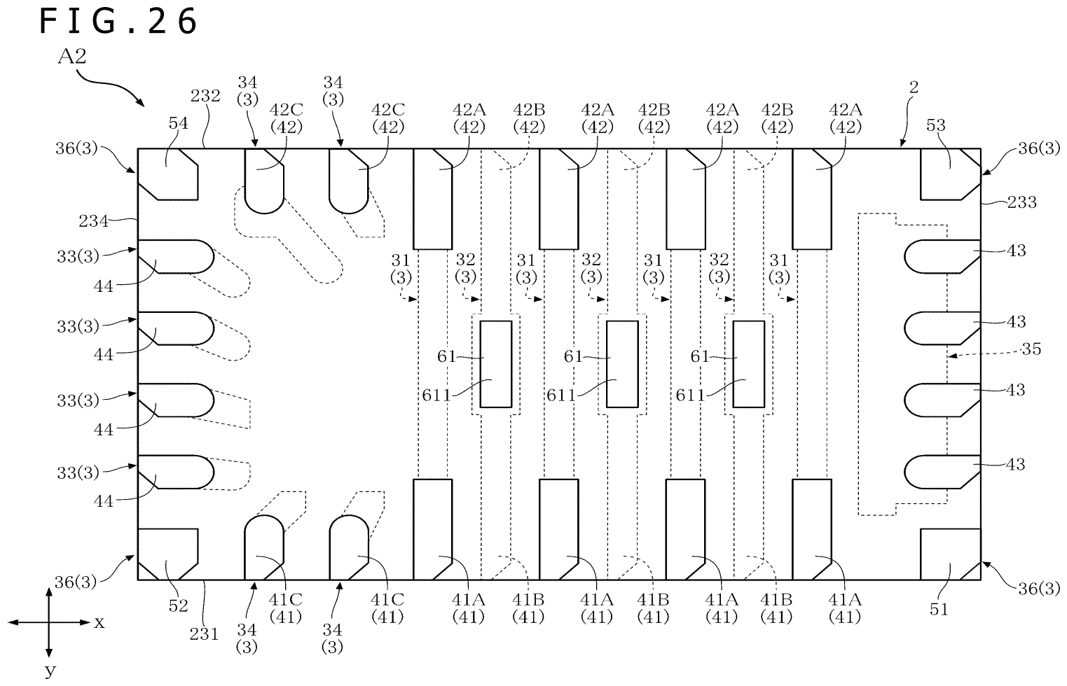

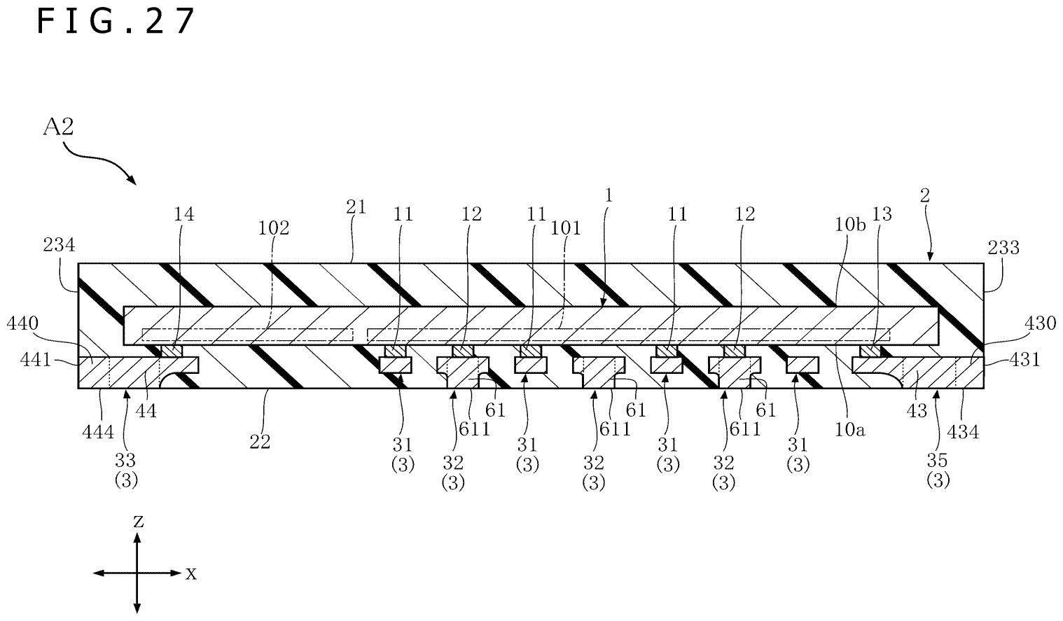

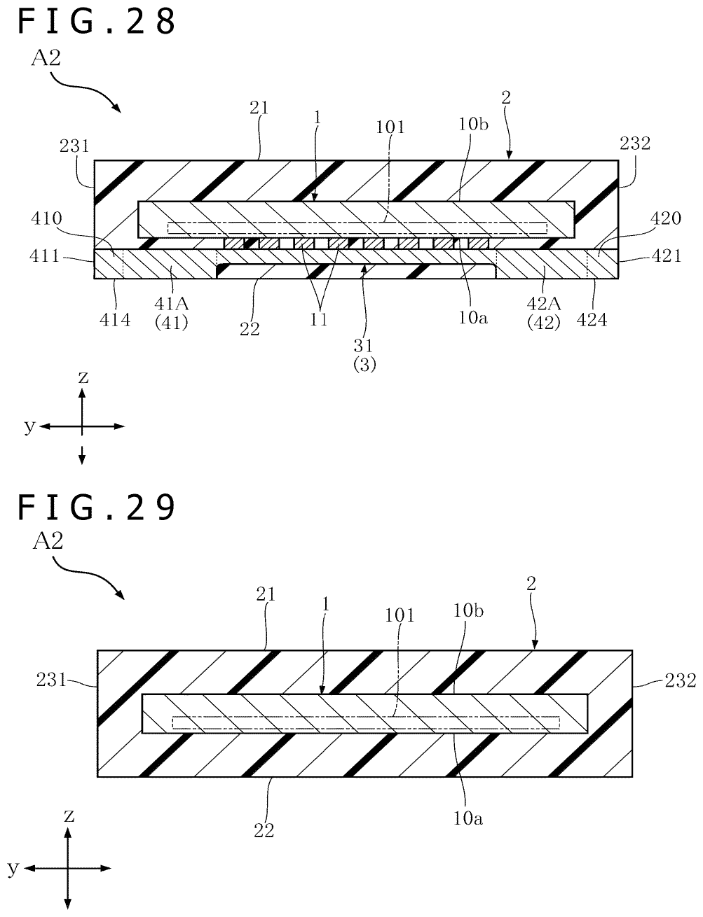

FIGS. 26 to 29 illustrate the electronic apparatus A2 according to a first modification of the first embodiment. As illustrated in FIGS. 26 to 29, the electronic apparatus A2 is different from the electronic apparatus A1 in the following points. First, the resin member 2 does not include the first resin recessed portion 241, the second resin recessed portion 242, the third resin recessed portion 243, and the fourth resin recessed portion 244. Secondly, each of the first side exposed portions 41A and 41C does not include the first side recessed portion 416. Thirdly, each of the second side exposed portions 42A and 42C does not include the second side recessed portion 426. Fourthly, each third side exposed portion 43 does not include the third side recessed portion 436. Fifthly, each fourth side exposed portion 44 does not include the fourth side recessed portion 446.

The electronic apparatus A2 illustrated in FIGS. 26 to 29 can be manufactured by, for example, the half-cut dicing not being performed in the manufacturing method of the electronic apparatus A1.

The electronic apparatus A2 can also be downsized while the short circuit of the leads 3 adjacent to each other is suppressed, as with the electronic apparatus A1.

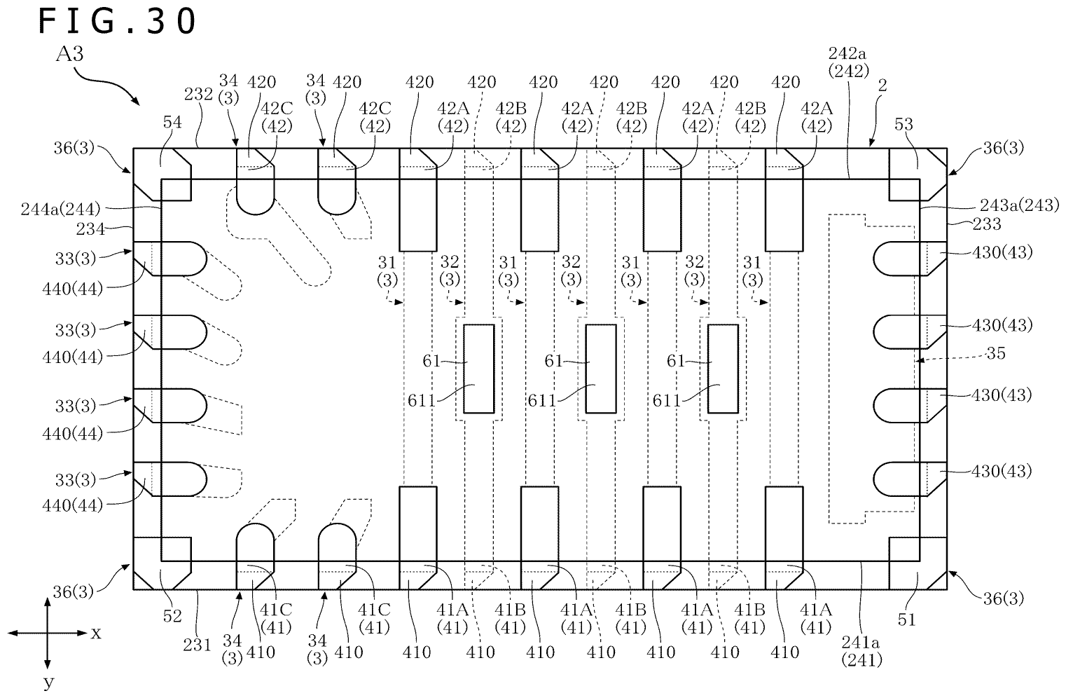

FIG. 30 illustrates the electronic apparatus A3 according to a second modification of the first embodiment. As illustrated in FIG. 30, the electronic apparatus A3 is different from the electronic apparatus A1 in the following points. First, each first tapered portion 410 of the plurality of first side exposed portions 41 is formed on the one side in the first direction y with respect to the first wall surface 241a of the first resin recessed portion 241. Secondly, each second tapered portion 420 of the plurality of second side exposed portions 42 is formed on the other side in the first direction y with respect to the second wall surface 242a of the second resin recessed portion 242. Thirdly, each third tapered portion 430 of the plurality of third side exposed portions 43 is formed on the one side in the second direction x with respect to the third wall surface 243a of the third resin recessed portion 243. Fourthly, each fourth tapered portion 440 of the plurality of fourth side exposed portions 44 is formed on the other side in the second direction x with respect to the fourth wall surface 244a of the fourth resin recessed portion 244.

The electronic apparatus A3 can also be downsized while the short circuit of the leads 3 adjacent to each other is suppressed, as with the electronic apparatus A1. In the electronic apparatus A3, the area of the part of each first side exposed portion 41, each second side exposed portion 42, each third side exposed portion 43, and each fourth side exposed portion 44 exposed from the resin back surface 22 can be large, and the strength of mounting on a circuit board of electronic equipment or other equipment can be increased.

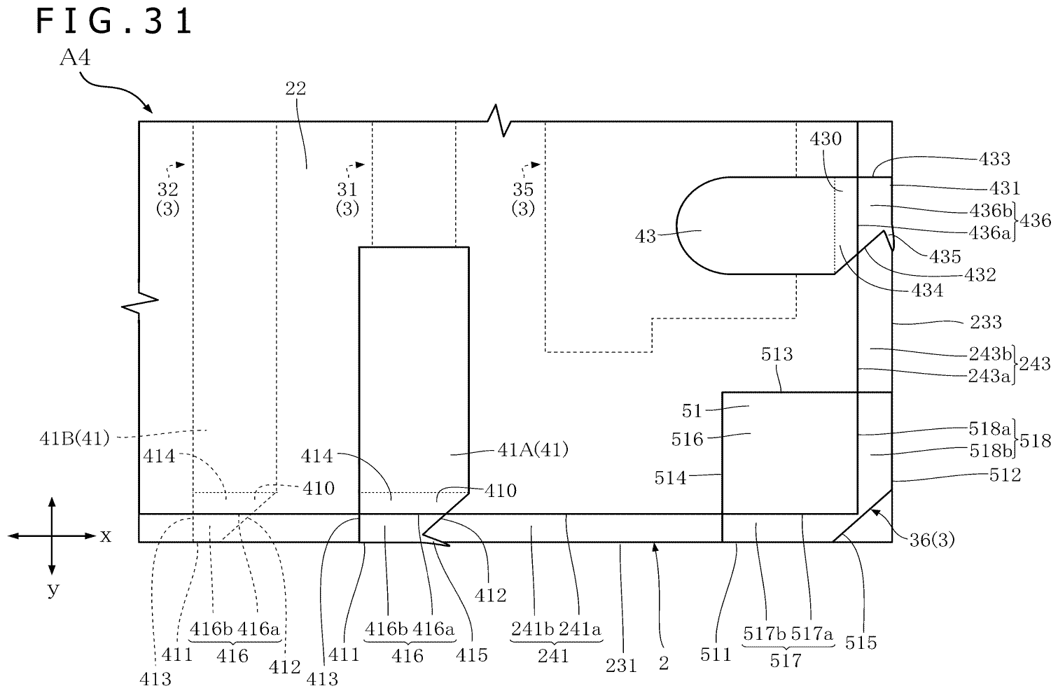

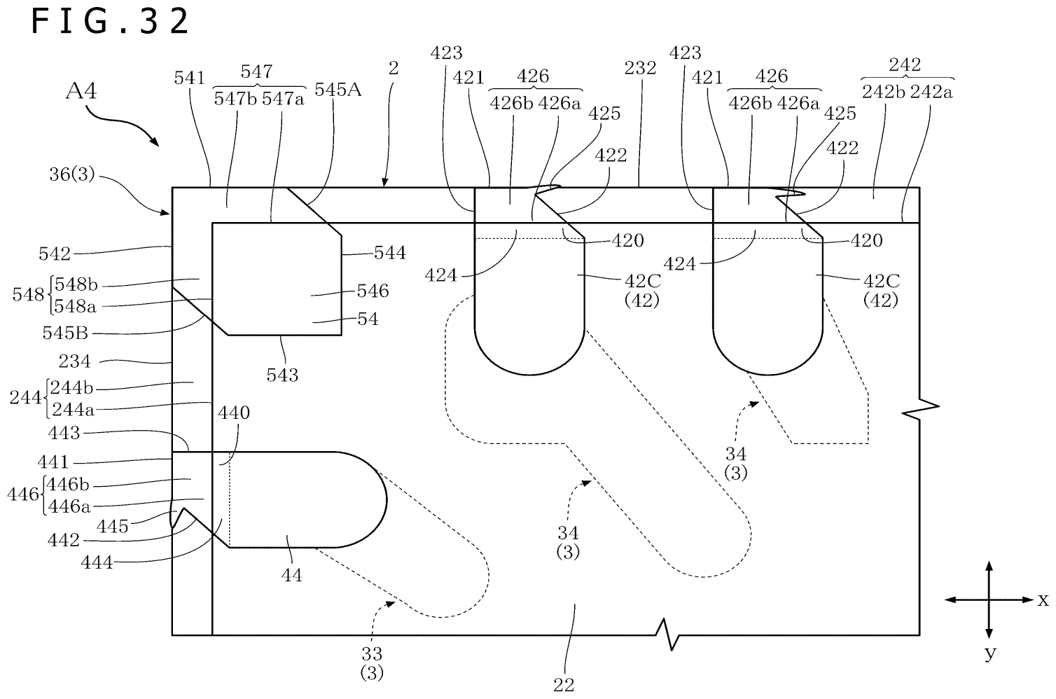

FIGS. 31 and 32 illustrate the electronic apparatus A4 according to a third modification of the first embodiment. FIGS. 31 and 32 are bottom views of main parts illustrating the electronic apparatus A4. As illustrated in FIGS. 31 and 32, the electronic apparatus A4 is different from the electronic apparatus A1 in the following points. First, the first tapered portion 410 further includes a first projection portion 415 in at least one of the plurality of first side exposed portions 41 as illustrated in FIG. 31. Secondly, the second tapered portion 420 further includes a second projection portion 425 in at least one of the plurality of second side exposed portions 42 as illustrated in FIG. 32. Thirdly, the third tapered portion 430 further includes a third projection portion 435 in at least one of the plurality of third side exposed portions 43 as illustrated in FIG. 31. Fourthly, the fourth tapered portion 440 further includes a fourth projection portion 445 in at least one of the plurality of fourth side exposed portions 44 as illustrated in FIG. 32.

As illustrated in FIG. 31, the first projection portion 415 is connected to the first front surface 411 and the first chamfered portion 412. The first projection portion 415 protrudes toward the one side in the second direction x in plan view (toward the direction of travel in the second dicing direction along the second direction x). As illustrated in FIG. 32, the second projection portion 425 is connected to the second front surface 421 and the second chamfered portion 422. The second projection portion 425 protrudes toward the one side in the second direction x in plan view (toward the direction of travel in the second dicing direction along the second direction x). As illustrated in FIG. 31, the third projection portion 435 is connected to the third front surface 431 and the third chamfered portion 432. The third projection portion 435 protrudes toward the one side in the first direction y in plan view (toward the direction of travel in the second dicing direction along the first direction y). As illustrated in FIG. 32, the fourth projection portion 445 is connected to the fourth front surface 441 and the fourth chamfered portion 442. The fourth projection portion 445 protrudes toward the one side in the first direction y in plan view (toward the direction of travel in the second dicing direction in the first direction y).

Each of the first projection portion 415, the second projection portion 425, the third projection portion 435, and the fourth projection portion 445 is a metal burr accidentally formed in the manufacturing of the electronic apparatus A1 (in the full-cut dicing). The first projection portion 415, the second projection portion 425, the third projection portion 435, and the fourth projection portion 445 may not have the same shape. The electronic apparatus A4 may not include all of the first projection portion 415, the second projection portion 425, the third projection portion 435, and the fourth projection portion 445, and the electronic apparatus A4 may include at least one of them.

The electronic apparatus A4 can also be downsized while the short circuit of the leads 3 adjacent to each other is suppressed, as with the electronic apparatus A1. In addition, the first tapered portion 410, the second tapered portion 420, the third tapered portion 430, and the fourth tapered portion 440 of the electronic apparatus A4 can reserve the distance between the cut parts of the leads 3. That is, the electronic apparatus A4 can suppress the short circuit of the leads 3 even when the electronic apparatus A4 includes the first projection portion 415, the second projection portion 425, the third projection portion 435, and the fourth projection portion 445 that are metal burrs which may be generated in the cutting. Hence, a process for removal of the metal burrs does not have to be executed after the full-cut dicing. The manufacturing process can thus be simplified, and the manufacturing cost can be reduced.

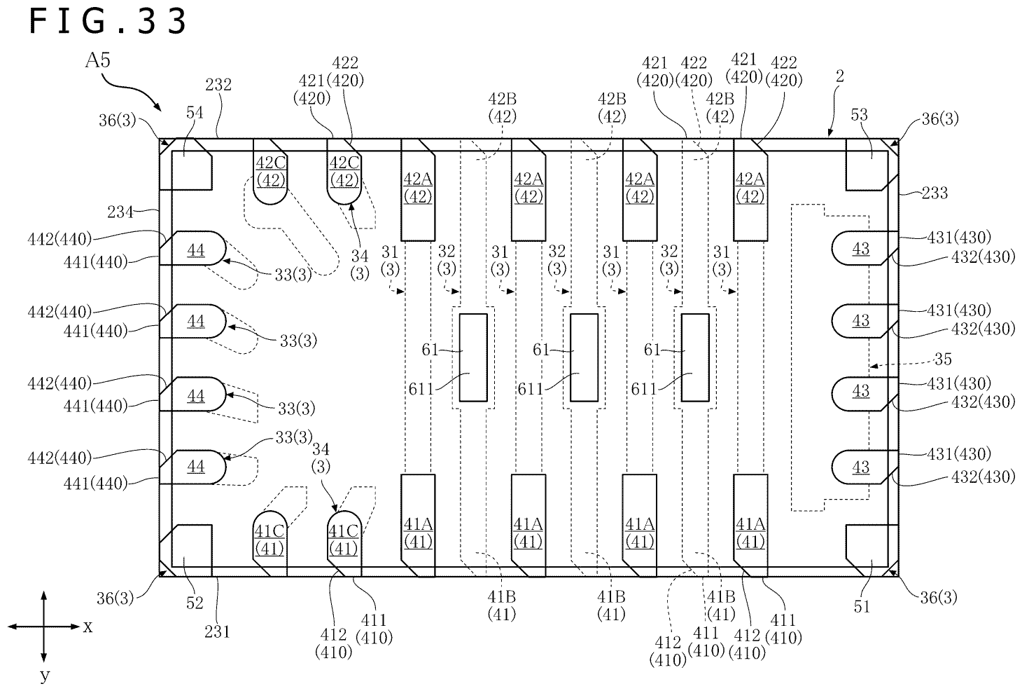

FIG. 33 illustrates an electronic apparatus A5 according to a fourth modification of the first embodiment. As illustrated in FIG. 33, the electronic apparatus A5 is different from the electronic apparatus A1 in the following points. First, the first chamfered portion 412 in the first tapered portion 410 of each first side exposed portion 41 is positioned on the other side in the second direction x with respect to the first front surface 411 instead of the one side in the second direction x. Secondly, the fourth chamfered portion 442 in the fourth tapered portion 440 of each fourth side exposed portion 44 is positioned on the other side in the first direction y with respect to the fourth front surface 441 instead of the one side in the first direction y.

In the electronic apparatus A5, it is preferable that the second dicing direction along the second direction x in cutting each first side exposed portion 41 be from the one side in the second direction x to the other side in the second direction x. It is also preferable that the second dicing direction along the first direction y in cutting each fourth side exposed portion 44 be from the one side in the first direction y to the other side in the first direction y. Note that, in the example illustrated in FIG. 33, the second dicing direction is taken into account to appropriately change the shapes (positions of chamfered portions) of the first corner exposed portion 51, the second corner exposed portion 52, the third corner exposed portion 53, and the fourth corner exposed portion 54.

The electronic apparatus A5 can also be downsized while the short circuit of the leads 3 adjacent to each other is suppressed, as with the electronic apparatus A1.

In the first embodiment and the modifications of the first embodiment, other leads 3 are not arranged on the one side in the second direction x and the one side in the first direction y of the first corner exposed portion 51.

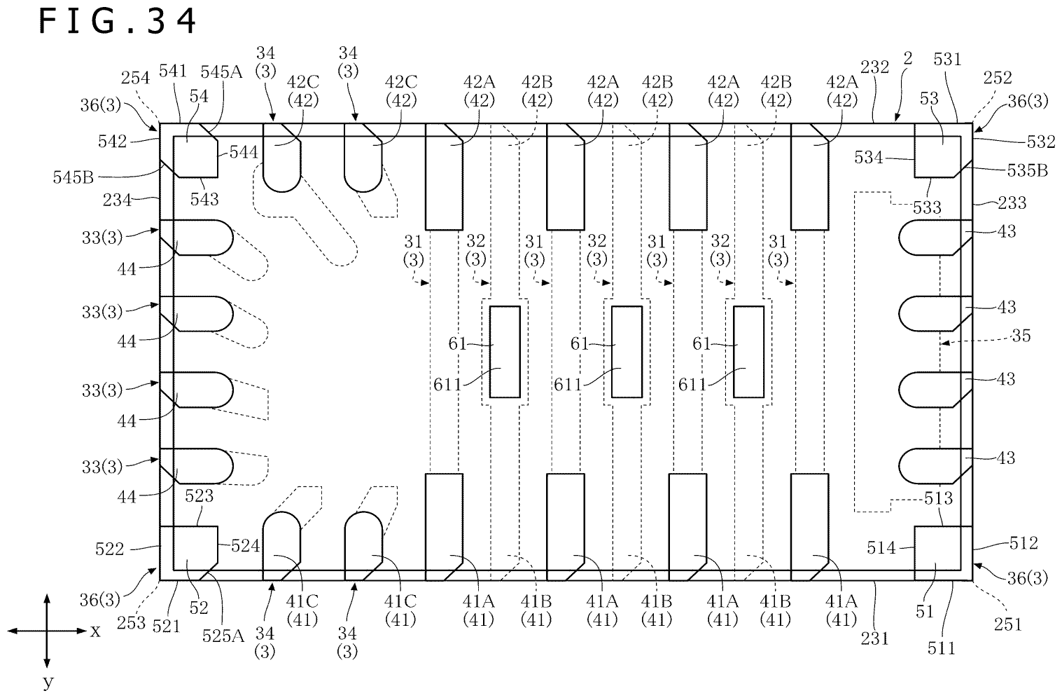

Accordingly, the possibility of short circuit in the other leads 3 is low even if metal burrs are generated in the first corner exposed portion 51 as a result of the full-cut dicing. Hence, the chamfered portion 515 may not be formed on the first corner exposed portion 51 as illustrated in FIG. 34. In addition, the other leads 3 are not arranged on the one side in the first direction y of the second corner exposed portion 52. Hence, the chamfered portion 525B may not be formed on the second corner exposed portion 52 as illustrated in FIG. 34. Similarly, the other leads 3 are not arranged on the one side in the second direction x of the third corner exposed portion 53. Hence, the chamfered portion 535A may not be formed on the third corner exposed portion 53 as illustrated in FIG. 34. Note that, in the example illustrated in FIG. 34, the first corner exposed portion 51 overlaps the first resin corner portion 251 including the first resin side surface 231 and the third resin side surface 233, in plan view. The third corner exposed portion 53 overlaps the second resin corner portion 252 including the second resin side surface 232 and the third resin side surface 233, in plan view. The second corner exposed portion 52 overlaps the third resin corner portion 253 including the first resin side surface 231 and the fourth resin side surface 234, in plan view, and the fourth corner exposed portion 54 overlaps the fourth resin corner portion 254 including the second resin side surface 232 and the fourth resin side surface 234, in plan view.

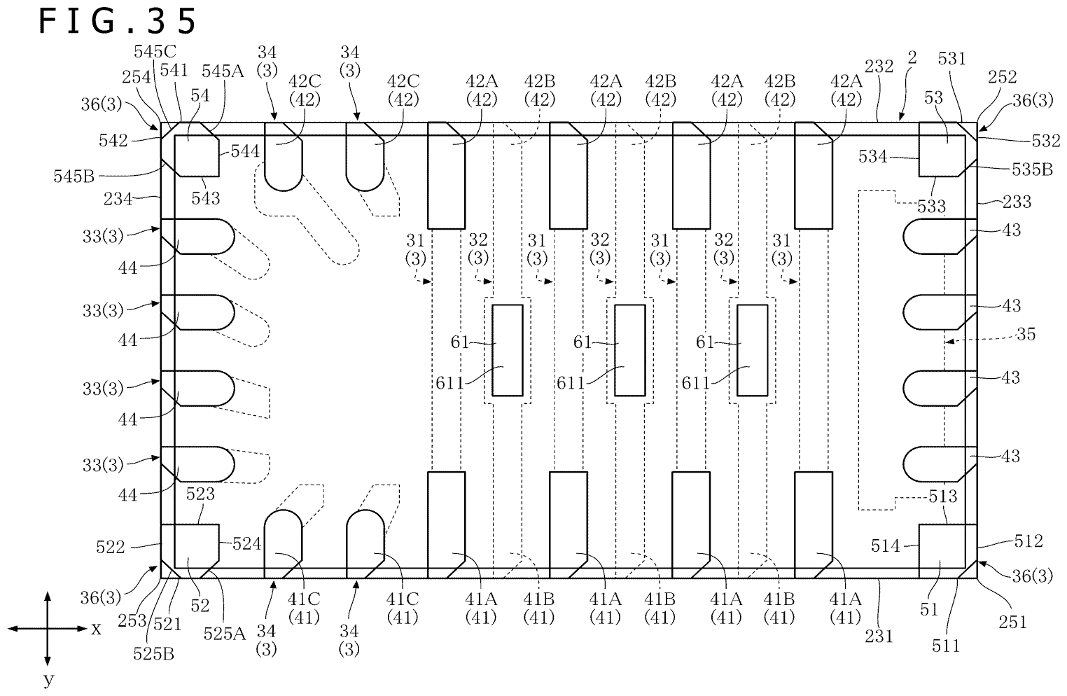

In the first embodiment and the modifications of the first embodiment, the first corner exposed portion 51 may be covered by a first resin corner portion 251, the second corner exposed portion 52 may be covered by a third resin corner portion 253, the third corner exposed portion 53 may be covered by a second resin corner portion 252, and the fourth corner exposed portion 54 may be covered by a fourth resin corner portion 254 as illustrated in FIG. 35, to prevent the first corner exposed portion 51, the second corner exposed portion 52, the third corner exposed portion 53, and the fourth corner exposed portion 54 from falling out from the resin member 2. In the electronic apparatus illustrated in FIG. 35, the fourth corner exposed portion 54 includes a chamfered portion 545C from the end surface 541 to the end surface 542, when compared with the fourth corner exposed portion 54 of the electronic apparatus A1. Note that, in the example illustrated in FIG. 35, the second corner exposed portion 52 includes a pair of chamfered portions 525A and 525B connected to both sides of the end surface 521 in the second direction x. In the example illustrated in FIG. 35, the end surface 521 corresponds to the “first end surface” described in the claims, and each of the chamfered portions 525A and 525B corresponds to the “third chamfered portion” described in the claims. The fourth corner exposed portion 54 includes a pair of chamfered portions 545A and 545C connected to both sides of the end surface 541 in the second direction x. In the example illustrated in FIG. 35, the end surface 541 corresponds to the “second end surface” described in the claims, and each of the chamfered portions 545A and 545C corresponds to the “fourth chamfered portion” described in the claims.

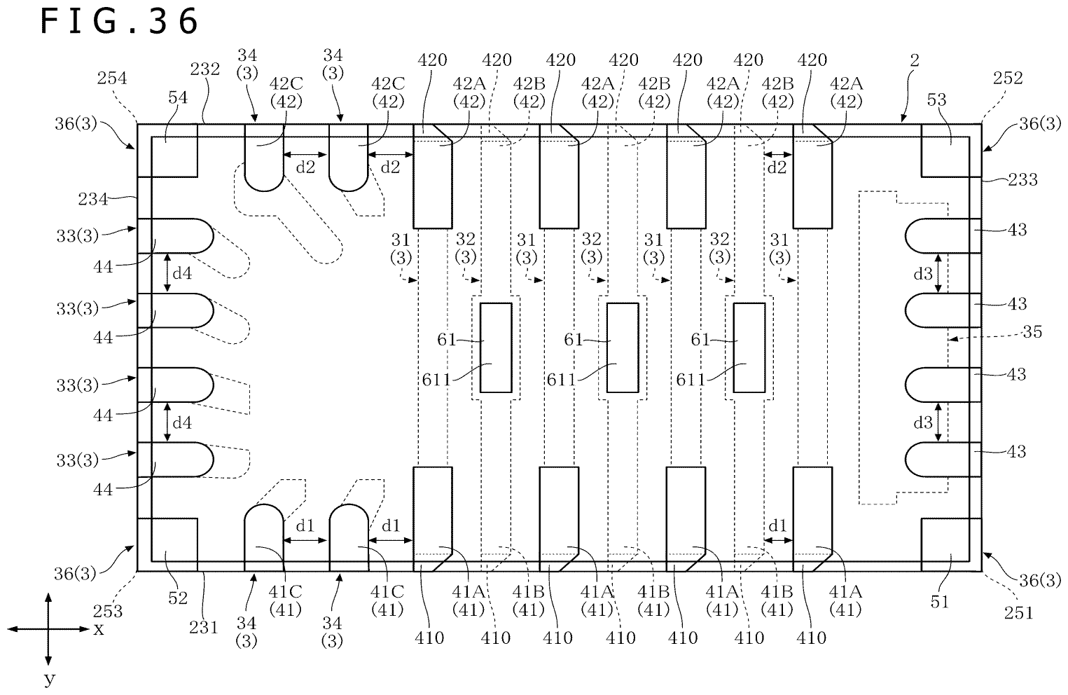

Although the first tapered portion 410 is provided on all of the plurality of first side exposed portions 41 in the first embodiment and the modifications of the first embodiment, the first tapered portion 410 may not be provided on all of the plurality of first side exposed portions 41. FIG. 36 is a bottom view illustrating an electronic apparatus according to such a modification. In the example illustrated in FIG. 36, the interval d1 between the first side exposed portion 41A and the first side exposed portion 41B adjacent to each other in the second direction x is small (for example, equal to or smaller than 200 μm), and short circuit may occur between the first side exposed portion 41A and the first side exposed portion 41B. Hence, the first tapered portion 410 is formed on each of the first side exposed portions 41A and 41B. On the other hand, the interval d1 between the first side exposed portions 41C adjacent to each other in the second direction x is large (for example, larger than 200 μm), and the possibility of short circuit of the first side exposed portions 41C is low. Hence, the first tapered portion 410 may not be formed on each first side exposed portion 41C as illustrated in FIG. 36. In this way, the first tapered portions 410 may be provided only on the first side exposed portions 41 in which there may be short circuit of the first side exposed portions 41 adjacent to each other in the second direction x. The same applies to the second tapered portions 420 in the plurality of second side exposed portions 42, the third tapered portions 430 in the plurality of third side exposed portions 43, and the fourth tapered portions 440 in the plurality of fourth side exposed portions 44. Note that the third side exposed portions 43 are formed on one fifth lead 35, and there is no potential difference between the third side exposed portions 43 (short circuit does not occur even when the portions are directly conducted). Hence, the third tapered portions 430 may not be provided on the third side exposed portions 43 from an electrical perspective, regardless of the size of the interval d3 (even if the interval d3 is small). In such a modification, the area exposed from the resin member 2 is large in the first side exposed portion 41 not including the first tapered portion 410, the second side exposed portion 42 not including the second tapered portion 420, the third side exposed portion 43 not including the third tapered portion 430, and the fourth side exposed portion 44 not including the fourth tapered portion 440. This can increase the strength of attachment to a circuit board of electronic equipment or other equipment. The same applies to the relation between each of the first corner exposed portion 51, the second corner exposed portion 52, the third corner exposed portion 53, and the fourth corner exposed portion 54 and the other leads 3 adjacent to the portions.

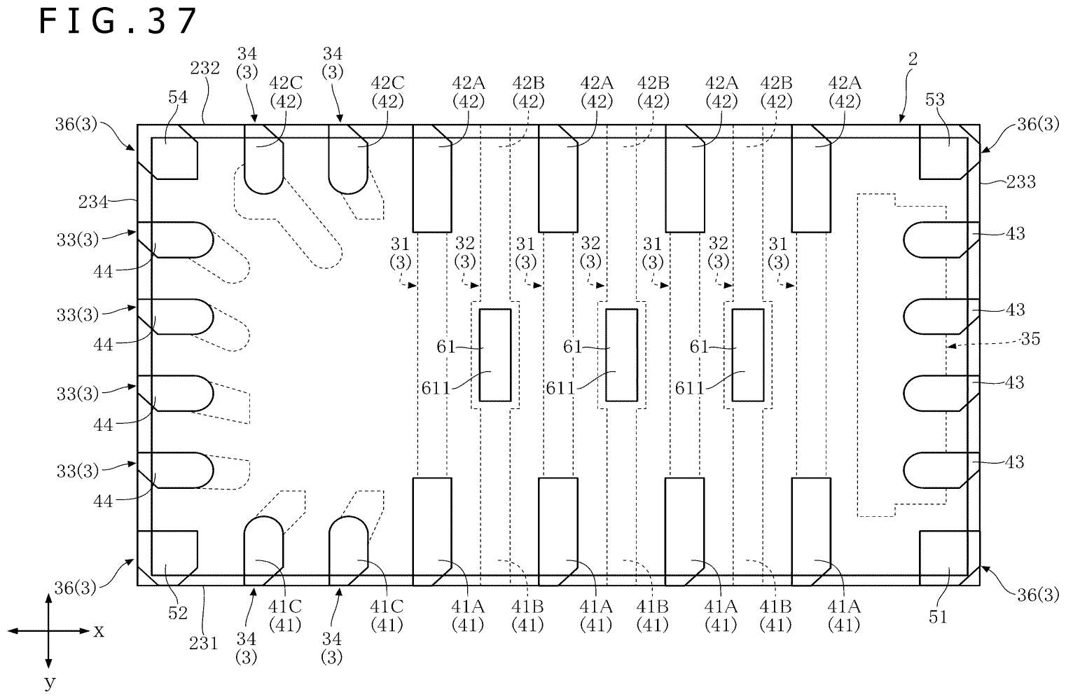

Although the first tapered portion 410 is formed on each first side exposed portion 41B in the examples illustrated in the first embodiment and the modifications of the first embodiment, the first tapered portion 410 may not be formed on each first side exposed portion 41B unlike the configuration. Although the second tapered portion 420 is formed on each second side exposed portion 42B in the illustrated examples, the second tapered portion 420 may not be formed on each second side exposed portion 42B unlike the configuration. For example, FIG. 37 illustrates an electronic apparatus according to such a modification. The first side exposed portion 41B of each second lead 32 is not exposed from the first resin recessed portion 241. In this configuration, the possibility of metal burrs being generated in the full-cut dicing is low (in other words, the possibility of metal burrs being generated in the full-cut dicing is high in the first side exposed portion 41A exposed from the first resin recessed portion 241). Accordingly, the electronic apparatus illustrated in FIG. 37 can be downsized while the short circuit of the leads 3 is suppressed, without the first tapered portion 410 being provided on each first side exposed portion 41B. Similarly, the second side exposed portion 42B of each second lead 32 is not exposed from the second resin recessed portion 242. Accordingly, the electronic apparatus illustrated in FIG. 37 can be downsized while the short circuit of the leads 3 is suppressed, without the second tapered portion 420 being provided on each second side exposed portion 42B.

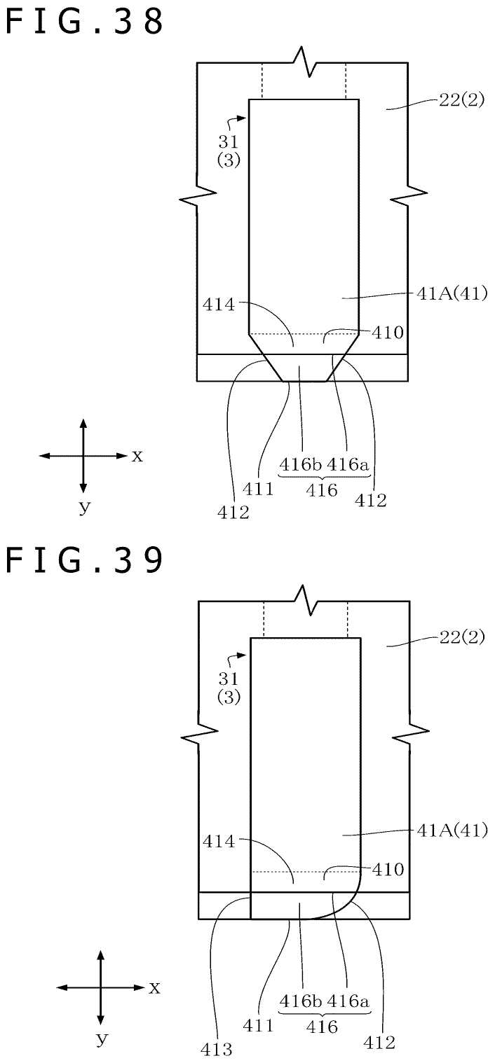

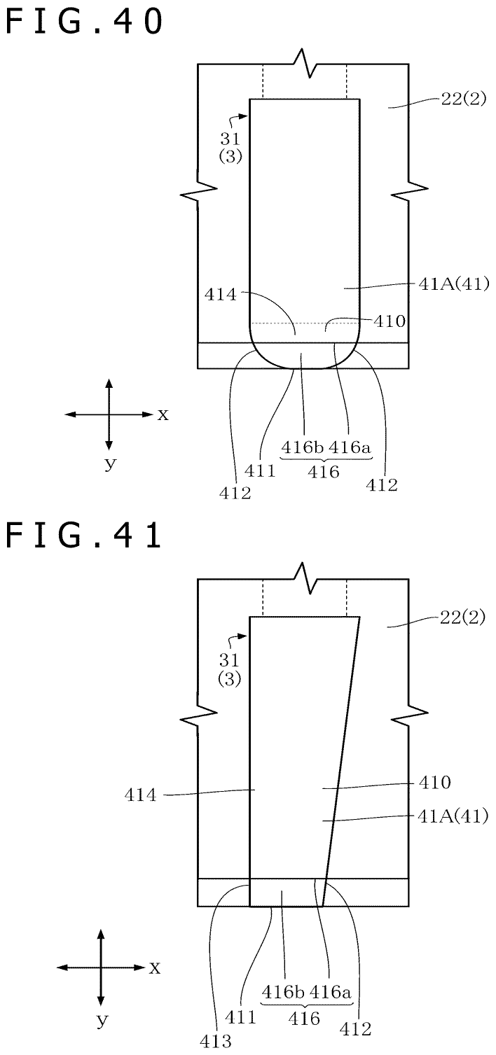

The shape of each first tapered portion 410 is not limited to the illustrated examples in the first embodiment and the modifications of the first embodiment. For example, the shape of each first tapered portion 410 may be one of the shapes illustrated in FIGS. 38 to 41. The first tapered portion 410 illustrated in FIG. 38 includes a pair of first chamfered portions 412. The pair of first chamfered portions 412 are connected to both ends of the first front surface 411 in the second direction x. Each of the pair of first chamfered portions 412 has a flat surface in the example illustrated in FIG. 38. The first chamfered portion 412 of the first tapered portion 410 illustrated in FIG. 39 has a curved surface that is projected in plan view. Although a pair of first chamfered portions 412 are formed on the first tapered portion 410 illustrated in FIG. 40, as in the example illustrated in FIG. 38, each of the pair of first chamfered portions 412 has a curved surface that is projected in plan view unlike the example illustrated in FIG. 38. The first tapered portion 410 illustrated in FIG. 41 corresponds to the entire first side exposed portion 41. That is, the first side exposed portion 41 includes the first tapered portion 410 in the example illustrated in FIG. 41. Although not illustrated and not described in detail, each of the second tapered portion 420, the third tapered portion 430, and the fourth tapered portion 440 may have a shape similar to one of the shapes illustrated in FIGS. 38 to 41.

### Second Embodiment

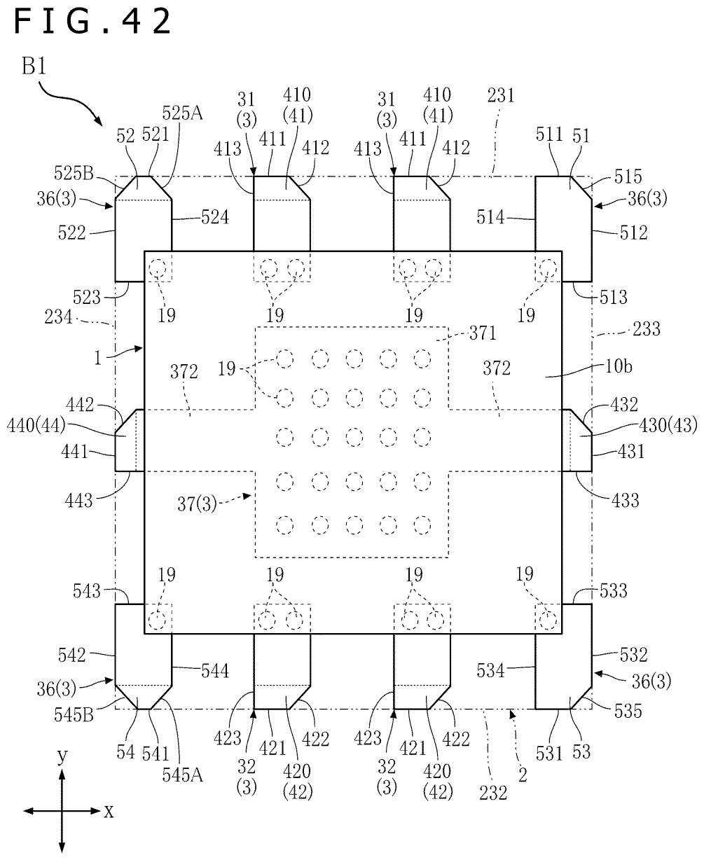

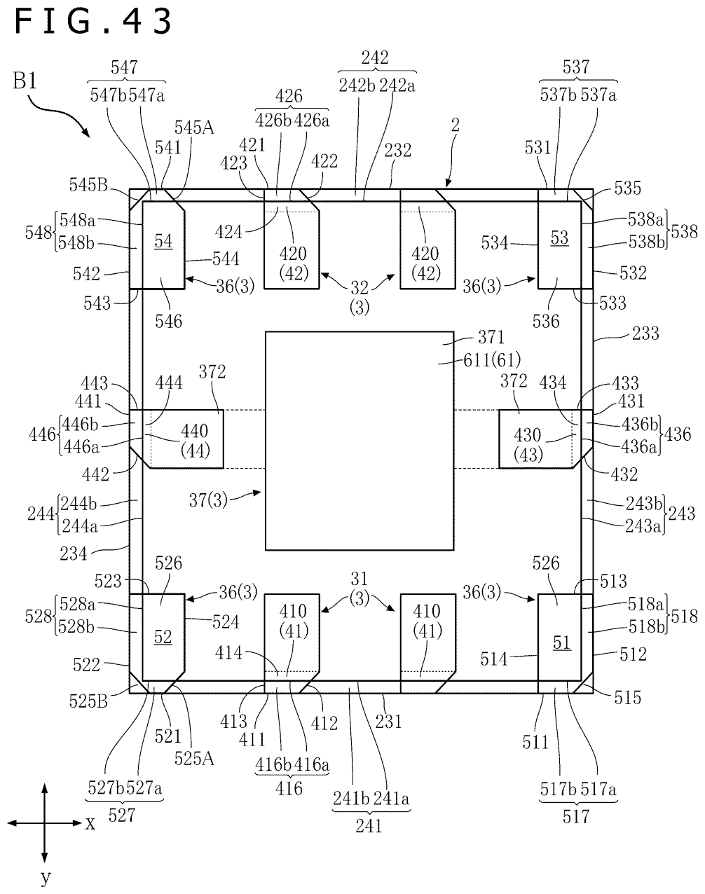

FIGS. 42 and 43 illustrate an electronic apparatus B1 according to a second embodiment of the present disclosure. As illustrated in FIGS. 42 and 43, the electronic apparatus B1 is mainly different from the electronic apparatus A1 in that the electronic apparatus B1 includes a plurality of leads 3 with a different configuration and further includes an island lead 37.

In the electronic apparatus B1, the plurality of leads 3 include the plurality of first leads 31, the plurality of second leads 32, and the plurality of sixth leads 36 as illustrated in FIGS. 42 and 43. The plurality of first leads 31 and some of the sixth leads 36 are positioned on the one side in the first direction y with respect to the island lead 37, and the plurality of second leads 32 and the rest of the sixth leads 36 are positioned on the other side in the first direction y with respect to the island lead 37. The plurality of leads 3 (the plurality of first leads 31, the plurality of second leads 32, and the plurality of sixth leads 36) are arranged around the island lead 37 in plan view.

The island lead 37 overlaps the electronic part 1 in plan view. The island lead 37 includes an island portion 371 and a pair of extension portions 372. The island portion 371 overlaps the electronic part 1 and is arranged at substantially the center of the electronic apparatus B1 in plan view. The pair of extension portions 372 extend in the second direction x from edges of the island portion 371 in the second direction x. Part of each of the pair of extension portions 372 on the side connected to the island portion 371 is covered by the resin member 2.

In the electronic apparatus B1, the electronic part 1 includes a plurality of electrodes 19. The plurality of electrodes 19 are arranged on the element main surface 10a. The plurality of electrodes 19 are appropriately attached to the plurality of leads 3 (the plurality of first leads 31, the plurality of second leads 32, and the plurality of sixth leads 36) and the island lead 37.

In the electronic apparatus B1, each of the plurality of first side exposed portions 41 is formed on a different one of the plurality of first leads 31. Each of the plurality of second side exposed portions 42 is formed on a different one of the plurality of second leads 32. The third side exposed portion 43 and the fourth side exposed portion 44 are formed on the island lead 37 (the pair of extension portions 372, respectively).

The electronic apparatus B1 can also be downsized while the short circuit of the leads 3 adjacent to each other is suppressed, as with the electronic apparatus A1.

Note that the configurations of the electronic apparatuses A2 to A5 and the other modifications may appropriately be adopted in the electronic apparatus B1. For example, the electronic apparatus B1 may not include the first resin recessed portion 241, the second resin recessed portion 242, the third resin recessed portion 243, and the fourth resin recessed portion 244 as in the electronic apparatus A2. The first tapered portion 410 may be formed on the one side in the first direction y with respect to the first wall surface 241a in the electronic apparatus B1 as in the electronic apparatus A3. The second tapered portion 420, the third tapered portion 430, and the fourth tapered portion 440 may be formed on the other side in the first direction y with respect to the second wall surface 242a, on the one side in the second direction x with respect to the third wall surface 243a, and on the other side in the second direction x with respect to the fourth wall surface 244a, respectively. The first tapered portion 410 may further include the first projection portion 415 in at least one of the plurality of first side exposed portions 41 in the electronic apparatus B1 as in the electronic apparatus A4. The second tapered portion 420 may further include the second projection portion 425 in at least one of the plurality of second side exposed portions 42. The third tapered portion 430 may further include the third projection portion 435 in at least one of the plurality of third side exposed portions 43. The fourth tapered portion 440 may further include the fourth projection portion 445 in at least one of the plurality of fourth side exposed portions 44. In the electronic apparatus B1, the first chamfered portion 412 may be positioned on the other side in the second direction x with respect to the first front surface 411 in the first tapered portion 410 of each first side exposed portion 41, and the fourth chamfered portion 442 may be positioned on the other side in the first direction y with respect to the fourth front surface 441 in the fourth tapered portion 440 of each fourth side exposed portion 44, as with the electronic apparatus A5.

Next, an electronic apparatus B2 according to a modification of the second embodiment will be described.

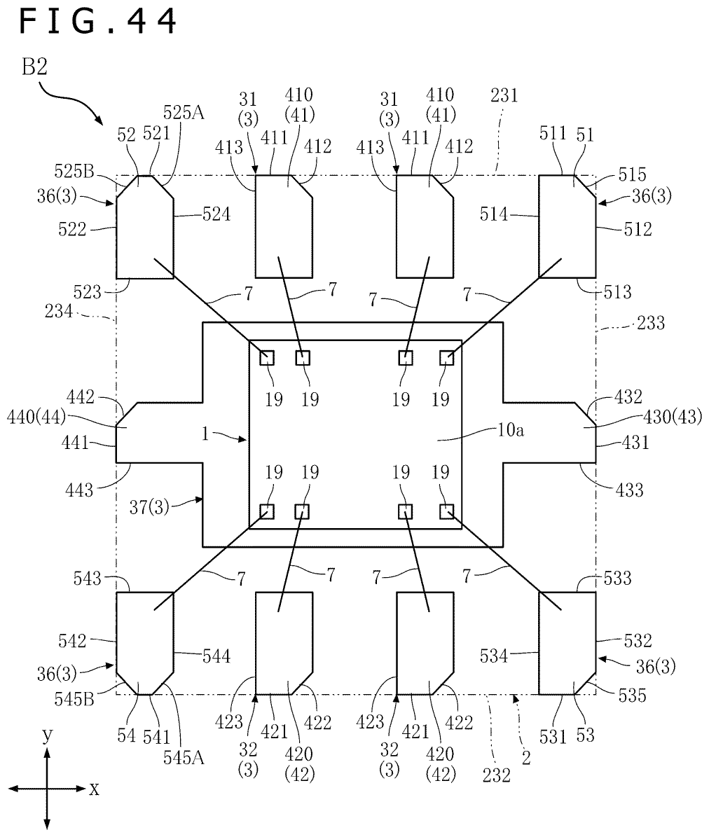

FIG. 44 illustrates the electronic apparatus B2 according to a modification of the second embodiment. As illustrated in FIG. 44, the electronic apparatus B2 is mainly different from the electronic apparatus B1 in that flip chip bonding is not used for the electronic part 1.

In the electronic apparatus B2, the element main surface 10a of the electronic part 1 faces the upper side in the thickness direction z, and the element back surface 10b faces the lower side in the thickness direction z. Accordingly, the element back surface 10b faces the plurality of leads 3 and the island lead 37 in the electronic apparatus B2.

The electronic apparatus B2 includes a plurality of wires 7 as illustrated in FIG. 44. The plurality of wires 7 are bonding wires for electrically connecting two sections separated from each other. Each of the plurality of wires 7 is attached to one of the electrodes 19 and one of the plurality of leads 3 of the electronic part 1 to electrically connect them.

The electronic apparatus B2 can also be downsized while the short circuit of the leads 3 adjacent to each other is suppressed, as with the electronic apparatus B1. That is, the electronic apparatus according to an embodiment of the present disclosure is not limited to the electronic apparatus in which the flip chip bonding is used for the electronic part 1. The electronic apparatus according to an embodiment of the present disclosure may be the electronic apparatus in which the bonding wires are used for the electronic part 1.

The electronic apparatus according to an embodiment of the present disclosure is not limited to the embodiments described above. Specific configurations of the components of the electronic apparatus according to an embodiment of the present disclosure can be freely designed and changed in various ways. For example, the electronic apparatus according to an embodiment of the present disclosure includes embodiments related to the following supplements.

### [Supplement 1]

An electronic apparatus including:
an electronic part;
a resin member that covers the electronic part; and
a plurality of leads each electrically connected to the electronic part, in which
the resin member includes a first resin side surface facing one side in a first direction orthogonal to a thickness direction of the resin member,
the plurality of leads include a plurality of first side exposed portions arranged along the first resin side surface, each of the plurality of first side exposed portions being exposed from the first resin side surface,
each of the plurality of first side exposed portions includes a first tapered portion that becomes narrower toward the first resin side surface as viewed in the thickness direction, and
the first tapered portion includes a first front surface that faces a same direction as the first resin side surface in the first direction and that is flush with the first resin side surface.

### [Supplement 2]

The electronic apparatus according to supplement 1, in which,
in each of the plurality of first side exposed portions, the first tapered portion includes a first chamfered portion that is connected to the first front surface as viewed in the thickness direction and that is formed on one side in a second direction orthogonal to the thickness direction and the first direction.

### [Supplement 3]

The electronic apparatus according to supplement 2, in which
each of the plurality of first side exposed portions further includes a first projection portion connected to the first front surface and the first chamfered portion and protruding toward one side in the second direction.

### [Supplement 4]

The electronic apparatus according to either supplement 2 or supplement 3, in which
the resin member includes a second resin side surface facing a side opposite the first resin side surface in the first direction,
the plurality of leads further include a plurality of second side exposed portions arranged along the second resin side surface, each of the plurality of second side exposed portions being exposed from the second resin side surface,
each of the plurality of second side exposed portions includes a second tapered portion that becomes narrower toward the second resin side surface as viewed in the thickness direction, and
the second tapered portion includes a second front surface that faces a same direction as the second resin side surface in the first direction and that is flush with the second resin side surface.

### [Supplement 5]

The electronic apparatus according to supplement 4, in which,
in each of the plurality of second side exposed portions, the second tapered portion includes a second chamfered portion that is connected to the second front surface as viewed in the thickness direction and that is formed on one side in the thickness direction and the second direction.

### [Supplement 6]

The electronic apparatus according to supplement 5, in which
each of the plurality of second side exposed portions further includes a second projection portion connected to the second front surface and the second chamfered portion and protruding toward one side in the second direction.

### [Supplement 7]

The electronic apparatus according to either supplement 5 or supplement 6, in which
the resin member includes
   a resin main surface and a resin back surface separated in the thickness direction,
   a first resin recessed portion recessed from the resin back surface and connected to the first resin side surface, and
   a second resin recessed portion recessed from the resin back surface and connected to the second resin side surface.

### [Supplement 8]

The electronic apparatus according to supplement 7, in which
each of the plurality of first side exposed portions includes a first side recessed portion connected to the first resin recessed portion.

### [Supplement 9]

The electronic apparatus according to supplement 8, in which
each of the plurality of second side exposed portions includes a second side recessed portion connected to the second resin recessed portion.

### [Supplement 10]

The electronic apparatus according to any one of supplements 7 to 9, in which
the first resin recessed portion includes a first wall surface that is connected to the resin back surface and that faces the same direction as the first resin side surface, and
the first tapered portion is formed on the one side in the first direction with respect to the first wall surface as viewed in the thickness direction.

### [Supplement 11]

The electronic apparatus according to supplement 10, in which
the second resin recessed portion includes a second wall surface that is connected to the resin back surface and that faces the same direction as the second resin side surface, and
the second tapered portion is formed on another side in the first direction with respect to the second wall surface as viewed in the thickness direction.

### [Supplement 12]

The electronic apparatus according to any one of supplements 4 to 11, in which
the resin member includes a third resin side surface facing one side in the second direction and a fourth resin side surface facing another side in the second direction, and
each of the third resin side surface and the fourth resin side surface is orthogonal to both the first resin side surface and the second resin side surface as viewed in the thickness direction.

### [Supplement 13]

The electronic apparatus according to supplement 12, in which
the plurality of leads further include a first corner exposed portion and a second corner exposed portion arranged across the plurality of first side exposed portions in the second direction,
the first corner exposed portion is exposed from the first resin side surface and the third resin side surface, and
the second corner exposed portion is exposed from the first resin side surface and the fourth resin side surface.

### [Supplement 14]

The electronic apparatus according to supplement 13, in which
the plurality of leads further include a third corner exposed portion and a fourth corner exposed portion arranged across the plurality of second side exposed portions in the second direction,
the third corner exposed portion is exposed from the second resin side surface and the third resin side surface, and
the fourth corner exposed portion is exposed from the second resin side surface and the fourth resin side surface.

### [Supplement 15]

The electronic apparatus according to supplement 14, in which
the first corner exposed portion overlaps a first resin corner portion including the first resin side surface and the third resin side surface, as viewed in the thickness direction, and
the third corner exposed portion overlaps a second resin corner portion including the second resin side surface and the third resin side surface, as viewed in the thickness direction.

### [Supplement 16]

The electronic apparatus according to either supplement 14 or supplement 15, in which
the second corner exposed portion includes a first end surface exposed from the first resin side surface and includes a pair of third chamfered portions connected to both sides of the first end surface in the second direction, and
the fourth corner exposed portion includes a second end surface exposed from the second resin side surface and includes a pair of fourth chamfered portions connected to both sides of the second end surface in the second direction.

### [Supplement 17]

The electronic apparatus according to any one of supplements 1 to 16, further including:
an island lead overlapping the electronic part as viewed in the thickness direction, in which
the plurality of leads are arranged around the island lead.

### [Supplement 18]

The electronic apparatus according to any one of supplements 1 to 17, in which
flip chip bonding is used for the electronic part.

What is claimed is:

1. An electronic apparatus comprising:
an electronic part;
a resin member that covers the electronic part; and
a plurality of leads each electrically connected to the electronic part, wherein
the resin member includes a first resin side surface facing one side in a first direction orthogonal to a thickness direction of the resin member,
the plurality of leads include a plurality of first side exposed portions arranged along the first resin side surface, each of the plurality of first side exposed portions being exposed from the first resin side surface,
each of the plurality of first side exposed portions includes a first tapered portion that becomes narrower toward the first resin side surface as viewed in the thickness direction, and
the first tapered portion includes a first front surface that faces a same direction as the first resin side surface in the first direction and that is flush with the first resin side surface.

2. The electronic apparatus according to claim 1, wherein,
in each of the plurality of first side exposed portions, the first tapered portion includes a first chamfered portion that is connected to the first front surface as viewed in the thickness direction and that is formed on one side in a second direction orthogonal to the thickness direction and the first direction.

3. The electronic apparatus according to claim 2, wherein
each of the plurality of first side exposed portions further includes a first projection portion connected to the first front surface and the first chamfered portion and protruding toward one side in the second direction.

4. The electronic apparatus according to claim 2, wherein
the resin member includes a second resin side surface facing a side opposite the first resin side surface in the first direction,
the plurality of leads further include a plurality of second side exposed portions arranged along the second resin side surface, each of the plurality of second side exposed portions being exposed from the second resin side surface,
each of the plurality of second side exposed portions includes a second tapered portion that becomes narrower toward the second resin side surface as viewed in the thickness direction, and
the second tapered portion includes a second front surface that faces a same direction as the second resin side surface in the first direction and that is flush with the second resin side surface.

5. The electronic apparatus according to claim 4, wherein,
in each of the plurality of second side exposed portions, the second tapered portion includes a second chamfered portion that is connected to the second front surface as viewed in the thickness direction and that is formed on one side in the thickness direction and the second direction.

6. The electronic apparatus according to claim 5, wherein
each of the plurality of second side exposed portions further includes a second projection portion connected to the second front surface and the second chamfered portion and protruding toward one side in the second direction.

7. The electronic apparatus according to claim 5, wherein
the resin member includes
a resin main surface and a resin back surface separated in the thickness direction,
a first resin recessed portion recessed from the resin back surface and connected to the first resin side surface, and
a second resin recessed portion recessed from the resin back surface and connected to the second resin side surface.

8. The electronic apparatus according to claim 7, wherein
each of the plurality of first side exposed portions includes a first side recessed portion connected to the first resin recessed portion.

9. The electronic apparatus according to claim 8, wherein
each of the plurality of second side exposed portions includes a second side recessed portion connected to the second resin recessed portion.

10. The electronic apparatus according to claim 7, wherein
the first resin recessed portion includes a first wall surface that is connected to the resin back surface and that faces the same direction as the first resin side surface, and
the first tapered portion is formed on the one side in the first direction with respect to the first wall surface as viewed in the thickness direction.

11. The electronic apparatus according to claim 10, wherein
the second resin recessed portion includes a second wall surface that is connected to the resin back surface and that faces the same direction as the second resin side surface, and
the second tapered portion is formed on another side in the first direction with respect to the second wall surface as viewed in the thickness direction.

12. The electronic apparatus according to claim 4, wherein
the resin member includes a third resin side surface facing one side in the second direction and a fourth resin side surface facing another side in the second direction, and
each of the third resin side surface and the fourth resin side surface is orthogonal to both the first resin side surface and the second resin side surface as viewed in the thickness direction.

13. The electronic apparatus according to claim 12, wherein
the plurality of leads further include a first corner exposed portion and a second corner exposed portion arranged across the plurality of first side exposed portions in the second direction,
the first corner exposed portion is exposed from the first resin side surface and the third resin side surface, and
the second corner exposed portion is exposed from the first resin side surface and the fourth resin side surface.

14. The electronic apparatus according to claim 13, wherein
the plurality of leads further include a third corner exposed portion and a fourth corner exposed portion arranged across the plurality of second side exposed portions in the second direction,
the third corner exposed portion is exposed from the second resin side surface and the third resin side surface, and
the fourth corner exposed portion is exposed from the second resin side surface and the fourth resin side surface.

15. The electronic apparatus according to claim 14, wherein
the first corner exposed portion overlaps a first resin corner portion including the first resin side surface and the third resin side surface as viewed in the thickness direction, and
the third corner exposed portion overlaps a second resin corner portion including the second resin side surface and the third resin side surface as viewed in the thickness direction.

16. The electronic apparatus according to claim 14, wherein
the second corner exposed portion includes a first end surface exposed from the first resin side surface and includes a pair of third chamfered portions connected to both sides of the first end surface in the second direction, and
the fourth corner exposed portion includes a second end surface exposed from the second resin side surface and includes a pair of fourth chamfered portions connected to both sides of the second end surface in the second direction.

17. The electronic apparatus according to claim 1, further comprising:
an island lead overlapping the electronic part as viewed in the thickness direction, wherein
the plurality of leads are arranged around the island lead.

18. The electronic apparatus according to claim 1, wherein
flip chip bonding is used for the electronic part.
